(19) United States
(12) Patent Application Publication
(10) Pub. No.: US 2024/0090220 A1
(43) Pub. Date: Mar. 14, 2024

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Jaemin JUNG, Suwon-si (KR); Byongju KIM, Suwon-si (KR); Wonjun PARK, Suwon-si (KR); Donghwa LEE, Suwon-si (KR); Changheon CHEON, Suwon-si (KR); Dongsung CHOI, Suwon-si (KR)

(21) Appl. No.: 18/367,619

(22) Filed: Sep. 13, 2023

(30) Foreign Application Priority Data
Sep. 14, 2022 (KR) 10-2022-0115802

(51) Int. Cl. H10B 43/27; G11C 5/06; G11C 16/04; H01L 25/065; H10B 41/10; H10B 41/27; H10B 41/35; H10B 41/40; H10B 43/10; H10B 43/35; H10B 43/40; H10B 80/00

(52) U.S. Cl. CPC H10B 43/27; G11C 5/063; G11C 16/0483; H01L 25/0652; H10B 41/10; H10B 41/27; H10B 41/35; H10B 41/40; H10B 43/10; H10B 43/35; H10B 43/40; H10B 80/00; H01L 2225/06506

(57) ABSTRACT

A semiconductor device includes a plurality of gate electrodes spaced apart from each other in a vertical direction on a substrate, a plurality of channel structures respectively penetrating a plurality of gate electrodes and extending in the vertical direction, each comprising a channel layer having a stacked structure of a first oxide semiconductor channel layer and a second oxide semiconductor channel layer which have different conductivities, and a gate insulating layer disposed between the channel layer and each of the plurality of gate electrodes, and a plurality of bit lines disposed on the plurality of channel structures and respectively connected to the plurality of channel structures, and the gate insulating layer, the first oxide semiconductor channel layer, and the second oxide semiconductor channel layer are sequentially disposed.

### CROSS-REFERENCE TO RELATED APPLICATION

This application is based on and claims priority under 35 U.S.C. § 119 to Korean Patent Application No. 10-2022-0115802, filed on Sep. 14, 2022, in the Korean Intellectual Property Office, the disclosure of which is incorporated by reference herein in its entirety.

### BACKGROUND

### 1. Field

Embodiments relate to a semiconductor device and an electronic system including the semiconductor device, and more particularly, to a semiconductor device having a vertical channel and an electronic system including the semiconductor device.

### 2. Description of the Related Art

In an electronic system requiring data storage, a semiconductor device capable of storing high-capacity data is desired. Accordingly, a method of increasing the data storage capacity of a semiconductor device has been researched. For example, as one of methods of increasing the data storage capacity of the semiconductor device, a semiconductor device including three-dimensionally arranged memory cells instead of two-dimensionally arranged memory cells has been proposed.

### SUMMARY

Embodiments may be directed to a semiconductor device including a plurality of gate electrodes spaced apart from each other in a vertical direction on a substrate; a plurality of channel structures respectively penetrating a plurality of gate electrodes and extending in the vertical direction, and each including a channel layer having a stacked structure of a first oxide semiconductor channel layer and a second oxide semiconductor channel layer which have different conductivities, and a gate insulating layer disposed between the channel layer and each of the plurality of gate electrodes; and a plurality of bit lines disposed on the plurality of channel structures and respectively connected to the plurality of channel structures, wherein the gate insulating layer, the first oxide semiconductor channel layer, and the second oxide semiconductor channel layer are sequentially disposed.

Embodiments may also be directed to a semiconductor device including a gate stack including a plurality of gate electrodes and a plurality of insulating layers alternately stacked on a substrate, a plurality of channel structures respectively filling a plurality of channel holes penetrating the gate stack; and a plurality of bit lines disposed on the plurality of channel structures and respectively connected to the plurality of channel structures, wherein each of the plurality of channel structures includes a gate insulating layer including a blocking dielectric layer, a charge storage layer, and a tunneling dielectric layer conformally and sequentially disposed on a sidewall of each of the plurality of channel holes; and a channel layer having a stacked structure of a first oxide semiconductor channel layer of an n-type conductivity and a second oxide semiconductor channel layer of a p-type conductivity on the gate insulating layer, wherein a band gap of the first oxide semiconductor channel layer has a greater value than that of a band gap of the second oxide semiconductor channel layer

Embodiments may also be directed to an electronic system including a main substrate, a semiconductor device on the main substrate; and a controller electrically connected to the semiconductor device on the main substrate, wherein the semiconductor device includes a plurality of gate electrodes spaced apart from each other in a vertical direction on the main substrate; a plurality of channel structures respectively penetrating the plurality of gate electrodes and extending in the vertical direction; a plurality of bit lines disposed on the plurality of channel structures and respectively connected to the plurality of channel structures, a peripheral circuit electrically connected to the plurality of gate electrodes and the plurality of bit lines, and an input/output pad electrically connected to the peripheral circuit, wherein each of the plurality of channel structures includes a channel layer having a stacked structure of a first oxide semiconductor channel layer and a second oxide semiconductor channel layer having different conductivities. A gate insulating layer is disposed between the channel layer and each of the plurality of gate electrodes, and the gate insulating layer, the first oxide semiconductor channel layer, and the second oxide semiconductor channel layer are sequentially disposed.

### BRIEF DESCRIPTION OF THE DRAWINGS

Features will become apparent to those of skill in the art by describing in detail exemplary embodiments with reference to the attached drawings in which:

FIG. 1 is a block diagram of a semiconductor device according to some embodiments;

FIG. 2 is an equivalent circuit diagram of a memory cell array of a semiconductor device according to some embodiments;

FIGS. 3 to 6 are diagrams illustrating a semiconductor device according to some embodiments;

FIGS. 7A to 7E are enlarged cross-sectional views of semiconductor devices according to some embodiments;

FIG. 8 is a perspective view of a semiconductor device according to some embodiments, and FIG. 9 is a cross-sectional view of the semiconductor device of FIG. 8;

FIGS. 10 and 11 are diagrams illustrating a semiconductor device according to some embodiments;

FIGS. 12A to 12E are enlarged cross-sectional views of semiconductor devices according to some embodiments;

FIG. 13 is a diagram illustrating a semiconductor device according to some embodiments;

FIG. 14 is a schematic view of an electronic system including a semiconductor device according to some embodiments;

FIG. 15 is a schematic perspective view of an electronic system including a semiconductor device, according to some embodiments; and

FIG. 16 is a schematic cross-sectional view of a semiconductor package according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

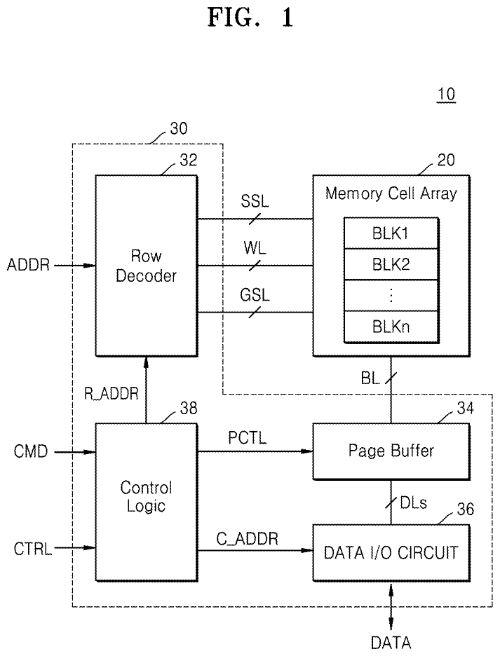

FIG. 1 is a block diagram of a semiconductor device according to some embodiments. Referring to FIG. 1, a semiconductor device 10 may include a memory cell array 20 and a peripheral circuit 30. The memory cell array 20 may include a plurality of memory cell blocks BLK1, BLK2, . . . , BLKn. Each of the plurality of memory cell blocks BLK1, BLK2, . . . , BLKn may include a plurality of memory cells. The memory cell blocks BLK1, BLK2, . . . , BLKn may be connected to the peripheral circuit 30 through a bit line BL, a word line WL, a string selection line SSL, and a ground selection line GSL.

The peripheral circuit 30 may include a row decoder 32, a page buffer 34, a data input/output circuit 36, and a control logic 38. The peripheral circuit 30 may further include an input/output interface, column logic, a voltage generator, a pre-decoder, a temperature sensor, a command decoder, an address decoder, an amplifier circuit, etc.

The memory cell array 20 may be connected to the page buffer 34 through the bit line BL, and may be connected to the row decoder 32 through the word line WL, the string selection line SSL, and the ground selection line GSL. In the memory cell array 20, each of the plurality of memory cells included in the plurality of memory cell blocks BLK1, BLK2, . . . , BLKn may be a flash memory cell. The memory cell array 20 may include a three-dimensional (3D) memory cell array. The 3D memory cell array may include a plurality of NAND strings, and each NAND string may include a plurality of memory cells connected to a plurality of word lines WL vertically stacked on a substrate.

The peripheral circuit 30 may receive an address ADDR, a command CMD, and a control signal CTRL from the outside of the semiconductor device 10, and may transmit and receive data DATA from a device outside the semiconductor device 10.

The row decoder 32 may select at least one of the plurality of memory cell blocks BLK1, BLK2, . . . , BLKn in response to the address ADDR from the outside, and may select the word line WL of the selected memory cell block, the string selection line SSL, and the ground selection line GSL. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL The page buffer 34 may operate as a sense amplifier during a read operation to sense the data DATA stored in the memory cell array 20. The page buffer 34 may operate according to a control signal PCTL provided from the control logic 38.

The data input/output circuit 36 may be connected to the page buffer 34 through data lines DLs. The data input/output circuit 36 may receive the data DATA from a memory controller (not shown) during a program operation, and may provide the program data DATA to the page buffer 34 based on a column address C_ADDR provided from the control logic 38. The data input/output circuit 36 may provide the read data DATA stored in the page buffer 34 to the memory controller during a read operation based on the column address C_ADDR provided from the control logic 38.

The data input/output circuit 36 may transfer an input address or command to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide a row address R_ADDR to the row decoder 32 and the column address C_ADDR to the data input/output circuit 36. The control logic 38 may generate various internal control signals used in the semiconductor device 10 in response to the control signal CTRL. For example, the control logic 38 may adjust voltage levels provided to the word line WL and the bit line BL when performing a memory operation such as a program operation or an erase operation.

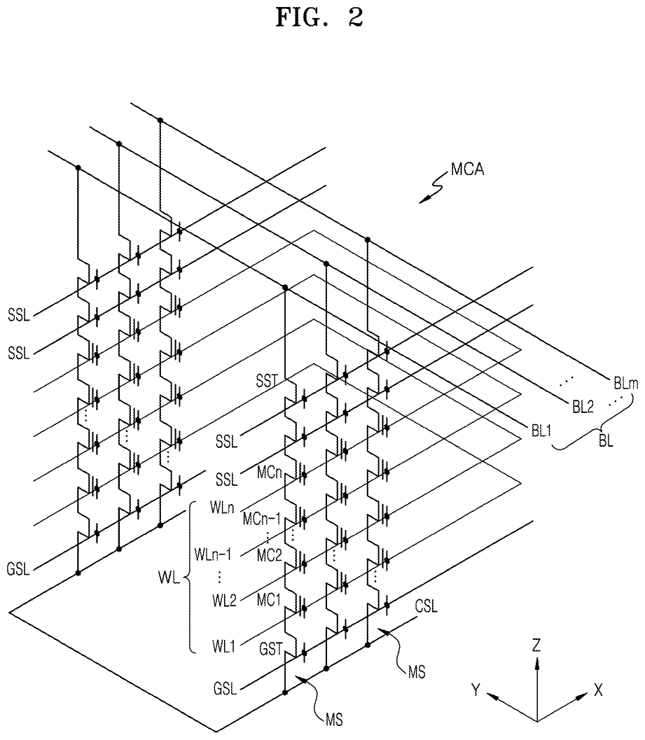

FIG. 2 is an equivalent circuit diagram of a memory cell array of a semiconductor device according to some embodiments.

Referring to FIG. 2, a memory cell array MCA may include a plurality of memory cell strings MS. The memory cell array MCA may include a plurality of bit lines BL: BL1, BL2, . . . , BLm, a plurality of word lines WL: WL1, WL2, . . . , WLn-1, WLn, at least one string selection line SSL, at least one ground selection line GSL, and a common source line CSL. A plurality of memory cell strings MS may be formed between the plurality of bit lines BL (BL1, BL2, . . . , BLm) and the common source line CSL. FIG. 2 illustrates a case where each of the plurality of memory cell strings MS includes two string selection lines SSL, as non-limiting examples. For example, in some implementations, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn-1, MCn. A drain region of the string selection transistor SST may be connected to the bit lines BL: BL1, BL2, . . . , BLm, and a source region of the ground selection transistor GST may be connected to the common source line CSL. The common source line CSL may be a region to which source regions of the plurality of ground selection transistors GST are commonly connected.

The string selection transistor SST may be connected to the string selection line SSL, and the ground selection transistor GST may be connected to the ground selection line GSL. The plurality of memory cell transistors MC1, MC2, . . . , MCn-1, MCn may be connected to the plurality of word lines WL: WL1, WL2, . . . , WLn-1, WLn, respectively.

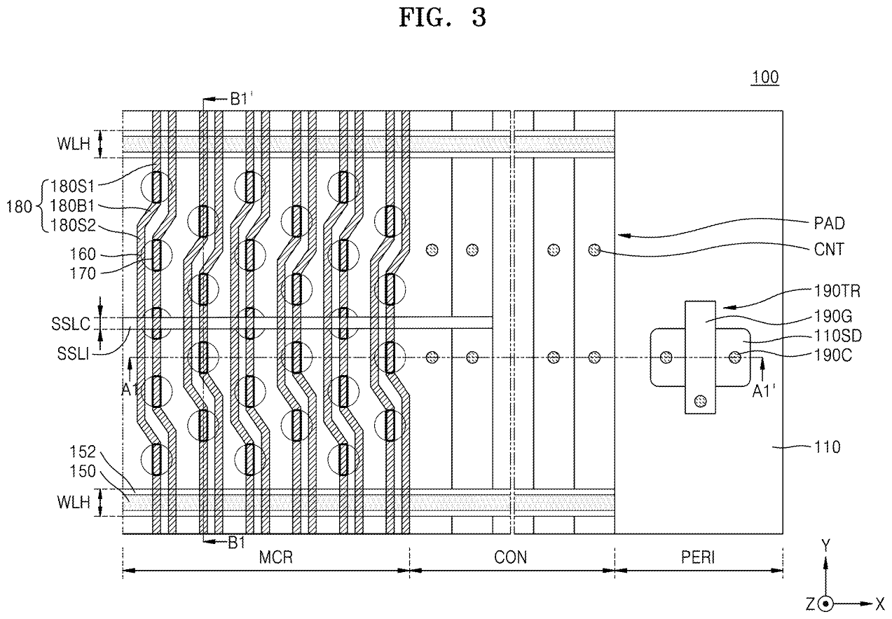

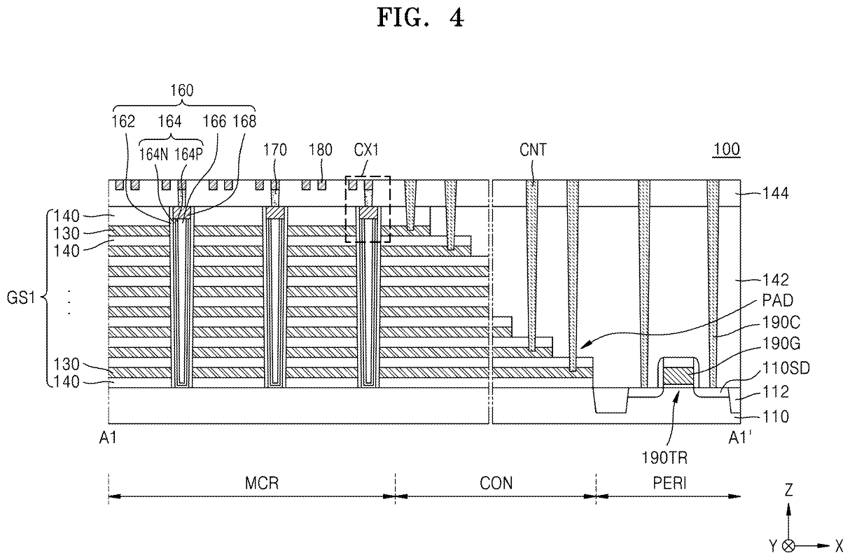

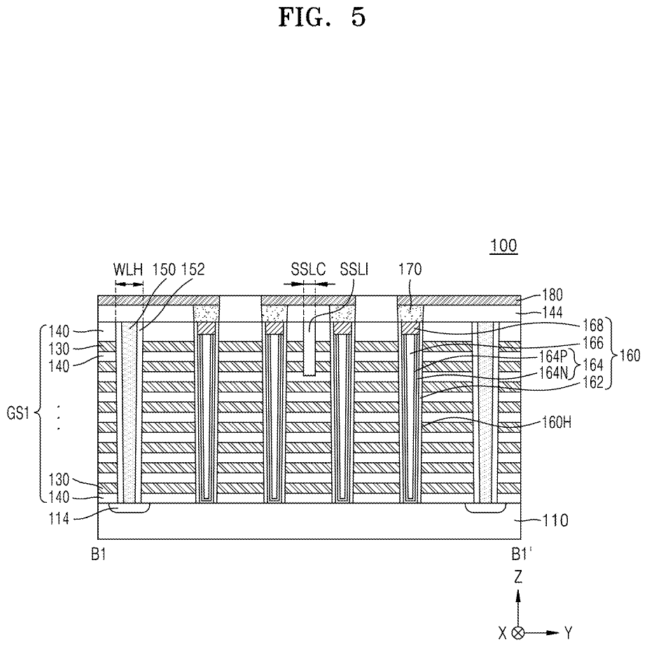

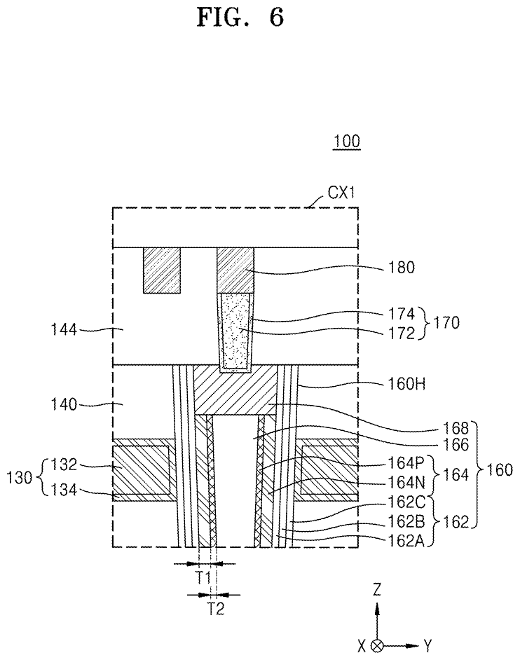

FIGS. 3 to 6 are diagrams illustrating a semiconductor device according to some embodiments. Specifically, FIG. 3 is a plan view illustrating a representative configuration of a semiconductor device according to some embodiments, FIG. 4 is a cross-sectional view taken along line A1-A1′ in FIG. 3, FIG. 5 is a cross-sectional view taken along line B1-B1′ in FIG. 3, and FIG. 6 is an enlarged view of a portion CX1 of FIG. 4.

Referring to FIGS. 3 to 6, the semiconductor device 100 may include a memory cell region MCR, a connection region CON, and a peripheral circuit region PERI that are horizontally arranged on a substrate 110. The memory cell region MCR may be a region in which a vertical channel structure NAND type memory cell array MCA driven in the manner described with reference to FIG. 2 is formed. The connection region CON may be a region where a pad portion PAD for electrical connection between the memory cell array MCA formed in the memory cell region MCR and the peripheral circuit region PERI is formed.

In the peripheral circuit region PERI, a peripheral circuit transistor 190TR and a peripheral circuit contact 190C may be disposed on the substrate 110. An active region AC may be defined on the substrate 110 by a device isolation layer 112, and the peripheral circuit transistor 190TR may be disposed on the active region AC. FIG. 3 illustrates one peripheral circuit transistor 190TR, as an example In some implementations, the semiconductor device 100 may include a plurality of peripheral circuit transistors 190TR formed on the active region AC. The peripheral circuit transistor 190TR may include a peripheral circuit gate 190G and a source/drain region 110SD disposed in a part of the substrate 110 on both sides of the peripheral circuit gate 190G. A plurality of peripheral circuit contacts 190C may be disposed on the peripheral circuit gate 190G and the source/drain region 110SD. For example, some of the plurality of peripheral circuit contacts 190C may be connected to the peripheral circuit gate 190G, and the others may be connected to the source/drain region 110SD.

The substrate 110 may include a semiconductor material such as a group IV semiconductor material, a group III-V semiconductor material, or a group II-VI semiconductor material. The group IV semiconductor material may include, for example, silicon (Si), germanium (Ge), or silicon-germanium (Si—Ge). The group III-V semiconductor material may include, for example, gallium arsenide (GaAs), indium phosphide (InP), gallium phosphide (GaP), indium arsenide (InAs), indium antimony (InSb), or indium gallium arsenide (InGaAs). The group II-VI semiconductor material may include, for example, zinc telluride (ZnTe) or cadmium sulfide (CdS). In some embodiments, the substrate 110 may be a bulk wafer or an epitaxial layer. In some embodiments, the substrate 110 may include a silicon-on-insulator (SOI) substrate or a germanium-on-insulator (GeOI) substrate.

A first gate stack GS1 may extend in a first horizontal direction (X direction) parallel to the upper surface of the substrate 110 and a second horizontal direction (Y direction) orthogonal to the first horizontal direction (X direction) on the substrate 110. The first gate stack GS1 may include a plurality of first gate electrodes 130 and a plurality of first insulating layers 140. The plurality of first gate electrodes 130 and the plurality of first insulating layers 140 may be alternately disposed in a vertical direction (Z direction) perpendicular to the upper surface of the substrate 110.

As shown in FIG. 6, the first gate electrode 130 may include a buried conductive layer 132 and a conductive barrier layer 134 surrounding upper, lower, and side surfaces of the buried conductive layer 132. For example, the buried conductive layer 132 may include a metal such as tungsten, nickel, cobalt, tantalum, etc., a metal silicide such as tungsten silicide, nickel silicide, cobalt silicide, tantalum silicide, etc., doped polysilicon, or combinations thereof. For example, the conductive barrier layer 134 may include titanium nitride, tantalum nitride, tungsten nitride, or combinations thereof. In some embodiments, a dielectric liner (not shown) may be further disposed between the conductive barrier layer 134 and the first insulating layer 140. For example, the dielectric liner may include a high-k material such as aluminum oxide.

The plurality of first gate electrodes 130 may correspond to the ground selection line GSL, the word lines WL: WL1, WL2, . . . , WLn-1, WLn, and the at least one string selection line SSL constituting the memory cell string MS (see FIG. 2). For example, the lowermost first gate electrode 130 may function as the ground selection line GSL. The at least one uppermost first gate electrode 130 may function as the string selection line SSL, and the remaining first gate electrode 130 may function as the word line WL. Accordingly, the memory cell string MS in which the ground selection transistor GST, the selection transistor SST, and the memory cell transistors MC1, MC2, . . . , MCn-1, and MCn therebetween are connected in series may be provided. In some embodiments, the uppermost two first gate electrodes 130 may function as the string selection lines SSL, as non-limiting examples. For example, in some embodiments, only the uppermost first gate electrode 130 may function as the string selection line SSL. In some embodiments, at least one of the first gate electrodes 130 may function as a dummy word line, as non-limiting examples.

As shown in FIG. 3, a plurality of gate stack isolation openings WLH penetrating the plurality of first gate electrodes 130 may extend on the substrate 110 in the first horizontal direction (X direction) parallel to the upper surface of the substrate 110. The first gate stack GS1 disposed between a pair of gate stack isolation openings WLH may constitute one block. The pair of gate stack isolation openings WLH may limit a width of the first gate stack GS1 in the second horizontal direction (Y direction).

A common source line 150 filling the inside of the gate stack isolation opening WLH and a gate stack isolation insulating layer 152 disposed on both sidewalls of the common source line 150 may be disposed on the substrate 110. A common source region 114 may be further formed in a part of the substrate 110 vertically overlapping the gate stack isolation opening WLH, such that the common source line 150 may be electrically connected to the common source region 114. In some embodiments, the common source region 114 may be an impurity region doped with a high-concentration n-type impurities, and may function as a source region supplying current to memory cells.

The gate stack isolation insulating layer 152 may be made of silicon oxide, silicon nitride, silicon oxynitride, or a low-k material. For example, the gate stack isolation insulating layer 152 may be made of a silicon oxide layer, a silicon nitride layer, SiON, SiOCN, SiCN, or combinations thereof.

The plurality of channel structures 160 may penetrate the first gate stack GS1 from the upper surface of the substrate 110 and extend in a vertical direction (Z direction) in the memory cell region MCR. The plurality of channel structures 160 may be spaced apart from each other at certain intervals in the first horizontal direction (X direction), the second horizontal direction (Y direction), and a third horizontal direction (e.g., diagonal direction). The plurality of channel structures 160 may be arranged in a zigzag shape or a staggered shape.

Each of the plurality of channel structures 160 may be disposed in a channel hole 160H. Each of the plurality of channel structures 160 may include a gate insulating layer 162, a channel layer 164, a buried insulating layer 166, and a conductive plug 168. The gate insulating layer 162 and the channel layer 164 may be sequentially disposed on the sidewall of the channel hole 160H. For example, the gate insulating layer 162 may be conformally disposed on the sidewall of the channel hole 160H, and the channel layer 164 may be conformally disposed on the sidewall and bottom portion of the channel hole 160H. The gate insulating layer 162 may be disposed between the plurality of first gate electrodes 130 and the channel layer 164. The conductive plug 168 contacting the channel layer 164 and blocking an entrance of the channel hole 160H may be disposed on the upper side of the channel hole 160H. In some embodiments, the buried insulating layer 166 filling a part of the channel hole 160H may be disposed on the channel layer 164, and the conductive plug 168 may contact the channel layer 164 and the buried insulating layer 166 and fill the upper side of the channel hole 160H. For example, the buried insulating layer 166 may fill a space defined by the channel layer 164 in the channel hole 160H. In some embodiments, the buried insulating layer 166 may be omitted, and the channel layer 164 may be formed in a pillar shape filling the remaining part of the channel hole 160H.

In some embodiments, the channel layer 164 may be disposed to contact the upper surface of the substrate 110 on the bottom portion of the channel hole 160H. In some other embodiments, a contact semiconductor layer (not shown) having a certain height on the substrate 110 may be further formed on the bottom portion of the channel hole 160H, and the channel layer 164 may be electrically connected to the substrate 110 through the contact semiconductor layer. For example, the contact semiconductor layer may include a silicon layer formed by a selective epitaxy growth (SEG) process using the substrate 110 disposed on the bottom portion of the channel hole 160H as a seed layer. In some embodiments, unlike what is shown in FIG. 4, the bottom surface of the channel layer 164 may be disposed at a lower vertical level than the upper surface of the substrate 110.

The channel layer 164 may be made of an oxide semiconductor material. Herein, the channel layer 164 may also be referred to as an “oxide semiconductor channel layer.” The channel layer 164 may include at least one oxide semiconductor material of a binary or ternary oxide semiconductor material including a first metal element, a ternary oxide semiconductor material including a first metal element and a second metal element different from each other. Moreover, the channel layer 164 may include a quaternary oxide semiconductor material including a first metal element, a second metal element, and a third metal element different from each other, or a quinary oxide semiconductor material including a first metal element, a second metal element, a third metal element, and a fourth metal element different from each other.

The binary oxide semiconductor material and the ternary oxide semiconductor material may include one of, for example, zinc oxide (ZnO), gallium oxide (GaO), tin oxide (TiO), copper oxide (Cu₂O), tellurium oxide (TeO), lead oxide (PbO), indium oxide (InO), bismuth oxide (BiO), tin oxide (SnO), nickel oxide (NiO), zinc oxynitride (ZnON), indium tungsten oxide (IWO), indium zinc oxide (IZO), gallium zinc oxide (GZO), tin zinc oxide (TZO), and tin gallium oxide (TGO), as non-limiting examples. The quaternary oxide semiconductor material and the quinary oxide semiconductor material may include any one of, for example, indium gallium zinc oxide (IGZO), indium gallium silicon oxide (IGSO), indium tin zinc oxide (ITZO), indium gallium tin oxide (IGTO), zirconium zinc tin oxide (ZZTO), hafnium indium zinc oxide (HIZO), gallium zinc tin oxide (GZTO), aluminum indium zinc oxide (AIZO), aluminum zinc tin oxide (AZTO) ytterbium gallium zinc oxide (YGZO), and indium gallium zinc tin oxide (IGZTO), as non-limiting examples.

In some embodiments, the channel layer 164 may include at least one crystallinity of amorphous, single crystalline, polycrystalline, spinel, or c-axis aligned crystalline (CAAC).

The channel layer 164 may have a stacked structure of a first oxide semiconductor channel layer 164N and a second oxide semiconductor channel layer 164P. The gate insulating layer 162, the first oxide semiconductor channel layer 164N, and the second oxide semiconductor channel layer 164P may be sequentially disposed on the sidewall of the channel hole 160H. The first oxide semiconductor channel layer 164N and the second oxide semiconductor channel layer 164P may be sequentially disposed on the bottom portion of the channel hole 160H. For example, the first oxide semiconductor channel layer 164N may conformally cover the gate insulating layer 162 covering the sidewall of the channel hole 160H and the bottom portion of the channel hole 160H. The second oxide semiconductor channel layer 164P may conformally cover the first oxide semiconductor channel layer 164N covering the sidewall of the channel hole 160H and the bottom portion of the channel hole 160H.

The first oxide semiconductor channel layer 164N and the second oxide semiconductor channel layer 164P may have different conductivity types. The first oxide semiconductor channel layer 164N may have a first conductivity type, and the second oxide semiconductor channel layer 164P may have a second conductivity type different from the first conductivity type. For example, the first conductivity type may be an n-type, the second conductivity type may be a p-type. The first oxide semiconductor channel layer 164N may be referred to as an n-type oxide semiconductor channel layer. The second oxide semiconductor channel layer 164P may be referred to as a p-type oxide semiconductor channel layer.

Referring to FIG. 6, on the sidewall of the channel hole 160H, that is, on the gate insulating layer 162, the first oxide semiconductor channel layer 164N may have a first thickness T1, and the second oxide semiconductor channel layer 164P may have a second thickness T2. In some embodiments, the first thickness T1 may be greater than the second thickness T2. For example, the first thickness T1 may be about 50 Å to about 100 Å, and the second thickness T2 may be about 30 Å to about 80 Å.

The gate insulating layer 162 covering the sidewall of the channel hole 160H may be formed, and then, an annealing process may be performed. A first oxide semiconductor material layer having the first thickness T1 and a second oxide semiconductor material layer having the thickness T2 may be sequentially formed on the sidewall and bottom portion of the channel hole 160H, and the first oxide semiconductor channel layer 164N and the second oxide semiconductor channel layer 164P may be formed. Then, an annealing process of forming the first oxide semiconductor channel layer 164N and the second oxide semiconductor channel layer 164P may be performed at a temperature condition of, for example, about 150° C. to about 300° C. In some implementations, the buried insulating layer 166 may be formed by performing an atomic layer deposition (ALD) process under room temperature conditions.

In some embodiments, the first oxide semiconductor channel layer 164N may be made of at least one oxide semiconductor material, for example, a quaternary oxide semiconductor material including a first metal element, a second metal element, and a third metal element different from each other, or a quinary oxide semiconductor material including a first metal element, a second metal element, a third metal element, and a fourth metal element different from each other. For example, the first oxide semiconductor channel layer 164N may include at least one of indium gallium tin oxide (IGTO), indium gallium zinc oxide (IGZO), or indium gallium zinc tin oxide (IGZTO).

In some embodiments, the second oxide semiconductor channel layer 164P may be made of a binary oxide semiconductor material including a first metal element. For example, the second oxide semiconductor channel layer 164P may include at least one of tin oxide (SnO), tellurium oxide (TeO), copper oxide (CuO), bismuth oxide (BiO), or nickel oxide (NiO).

In some embodiments, the first oxide semiconductor channel layer 164N and the second oxide semiconductor channel layer 164P may include at least one metal element that is the same. For example, the first oxide semiconductor channel layer 164N may be made of at least one oxide semiconductor material of a quaternary oxide semiconductor material including a first metal element, a second metal element, and a third metal element different from each other, or a quinary oxide semiconductor material including a first metal element, a second metal element, a third metal element, and a fourth metal element different from each other. The second oxide semiconductor channel layer 164P may be made of a binary oxide semiconductor material including the same first metal element as included in the first oxide semiconductor channel layer 164N. For example, the first metal element may be tin (Sn), and the first oxide semiconductor channel layer 164N may include at least one of indium gallium tin oxide (IGTO) or indium gallium zinc tin oxide (IGZTO) The second oxide semiconductor channel layer 164P may include tin oxide (SnO). The first oxide semiconductor channel layer 164N and the second oxide semiconductor channel layer 164P may be formed in-situ by commonly using a precursor including the first metal element in one chamber.

In some embodiments, a band gap of a material constituting the first oxide semiconductor channel layer 164N may have a greater value than that of a band gap of a material constituting the second oxide semiconductor channel layer 164P. For example, in some embodiments, a material forming the first oxide semiconductor channel layer 164N may have a band gap greater than or equal to 3 eV. A material forming the second oxide semiconductor channel layer 164P may have a band gap smaller than about 3 eV.

As shown in FIG. 6, the gate insulating layer 162 may have a structure including a tunneling dielectric layer 162A, a charge storage layer 162B, and a blocking dielectric layer 162C sequentially disposed on the outer wall of the channel layer 164. For example, the blocking dielectric layer 162C, the charge storage layer 162B, and the tunneling dielectric layer 162A may be sequentially and conformally disposed on the sidewall of the channel hole 164H. Relative thicknesses of the tunneling dielectric layer 162A, the charge storage layer 162B, and the blocking dielectric layer 162C constituting the gate insulating layer 162 are not limited to those illustrated in FIG. 6 and may be variously modified.

The tunneling dielectric layer 162A may include, for example, silicon oxide, silicon oxynitride, hafnium oxide, aluminum oxide, zirconium oxide, tantalum oxide, etc. The charge storage layer 162B is a region in which electrons passing through the tunneling dielectric layer 162A from the channel layer 164 may be stored, and may include, for example, silicon nitride, boron nitride, silicon boron nitride, or poly doped with impurities. For example, the blocking dielectric layer 162C may be made of silicon oxide, silicon nitride, or a metal oxide having a higher permittivity than that of silicon oxide. For example, the metal oxide may be made of hafnium oxide, aluminum oxide, zirconium oxide, tantalum oxide, or a combination thereof.

At least one uppermost first gate electrode 130 in one block may be divided into two parts in a plan view by a string selection line cut region SSLC. The string selection line cut region SSLC may penetrate the at least one uppermost first gate electrode 130 and extend in the first horizontal direction. In some embodiments, each of the uppermost two first gate electrodes 130 may be divided into two parts in a plan view by the string selection line cut region SSLC, as a non-limiting example. In some implementations, only one uppermost first gate electrode 130 may be divided into two parts in a plan view by the string selection line cut region SSLC. A string isolation insulating layer SSLI may be disposed in the string selection line cut region SSLC. The two parts may be spaced apart in the second horizontal direction (Y direction) with a string isolation insulating layer SSLI disposed therebetween. The two parts may configure the string selection line SSL described with reference to FIG. 2.

The first gate stack GS1 may extend from the memory cell region MCR to the connection region CON to configure the pad portion PAD in the connection region CON. In the connection region CON, the plurality of first gate electrodes 130 may extend to have shorter lengths in the first horizontal direction (X direction) with respect to a distance away from the upper surface of the substrate 110. The term “pad portion PAD” may refer to portions of the first gate electrode 130 arranged in a stepped shape in the connection region CON. A cover insulating layer 142 may be disposed on a portion of the first gate stack GS1 constituting the pad portion PAD. An upper insulating layer 144 may be disposed on the first gate stack GS1 and the cover insulating layer 142.

Although not shown, a plurality of dummy channel structures penetrating the first gate stack GS1 from the upper surface of the substrate 110 and extending in the vertical direction (Z direction) may be further formed in the connection region CON. The dummy channel structure may be formed to prevent leaning or bending of the first gate stack GS1 during the manufacturing process of the semiconductor device 100 and to secure structural stability. Each of the plurality of dummy channel structures may have a structure and shape similar to that of each of the plurality of channel structures 160.

A cell contact plug CNT penetrating the upper insulating layer 144 and the cover insulating layer 142 and connected to the first gate electrode 130 may be disposed in the connection region CON. The cell contact plug CNT penetrating the upper insulating layer 144 and the cover insulating layer 142 and further penetrating the first insulating layer 140 covering the first gate electrode 130 may be connected to the first gate electrode 130.

A plurality of bit line contacts 170 may penetrate the upper insulating layer 144 and contact the conductive plugs 168 of the plurality of channel structures 160. A plurality of bit lines 180 may be disposed on the plurality of bit line contacts 170. In some embodiments, the sidewall of the bit line 180 may be surrounded by the upper insulating layer 144. In other embodiments, the bit line 180 may be disposed on the upper surface of the upper insulating layer 144. An additional insulating layer surrounding the sidewall of the bit line 180 may be further disposed on the upper insulating layer 144.

In some embodiments, as shown in FIG. 3, the bit line 180 may include a first segment 180S1 extending in the second horizontal direction (Y direction), a second segment 180S2 spaced apart from the first segment 180S1 in the first horizontal direction (X direction) and extending in the second horizontal direction (Y direction), and a first bending portion 180B1 connecting the first segment 180S1 to the second segment 180S2.

In a plan view, the first bending portion 180B1 may be inclined at an inclination angle of about 20 degrees to about 70 degrees with respect to the second horizontal direction (Y direction) and may extend a certain length. In some embodiments, the first bending portion 180B1 may be inclined at an inclination angle of about 30 degrees to about 50 degrees with respect to the second horizontal direction (Y direction), as a non-limiting example. The inclination angle of the first bending portion 180B1 with respect to the second horizontal direction (Y direction) may vary depending on the size and arrangement of the channel structure 160.

In some embodiments, the first segment 180S1, the first bending portion 180B1, and the second segment 180S2 of the bit line 180 may be regions that are patterned simultaneously using a mask pattern formed by extreme ultraviolet (EUV) exposure. For example, a mask pattern may be formed using a photoresist material that is a photosensitive polymer material having chemical properties that are changed by exposure to EUV having a wavelength less than 13.5 nm or 11 nm. The bit line 180 may be patterned into a shape including the first segment 180S1, the first bending portion 180B1, and the second segment 180S2 using the mask pattern. In this case, even if the inclination angle of the first bending portion 180B1 was to be relatively large and the distance between the bit line 180 and the adjacent bit line 180 was to be relatively small, the bit line 180 could still be formed in a line shape having a relatively uniform width over its entire length.

In some embodiments, the bit line contact 170 may include a contact conductive layer 172 and a conductive barrier layer 174 surrounding side and bottom surfaces of the contact conductive layer 172. The bit line contact 170 may be arranged to overlap the central portion of the channel structure 160, such that a relatively large contact area between the bit line contact 170 and the channel structure 160 may be secured. Accordingly, the channel structure 160 and the bit line 180 may be disposed without forming an additional stud therebetween. For example, the upper surface of the bit line contact 170 may contact the bottom surface of the bit line 180, and the bottom surface of the bit line contact 170 may contact the upper surface of the channel structure 160.

In general, when the uppermost two first gate electrodes 130 in one block are separated into two parts in a plane by a string selection line cut region SSLC, two channel structures 160 spaced apart in the second horizontal direction Y need to be respectively connected to two bit lines 180 (e.g., an odd-numbered bit line and an even-numbered bit line) disposed adjacent to each other. As the size of the channel structure 160 and the pitch of the bit line 180 continues to decrease, a method of forming the bit line 180 by double patterning technology (DPT) has been proposed. In this case, the bit line 180 may be limited to a repetitive line shape with the same width or the same space. In this case, the center line of the bit line 180 and the center line of the channel structure 160 may not coincide with each other in a plan view. In order to secure sufficient contact resistance between the channel structure 160 and the bit line contact 170, it may be desirable to dispose an additional stud between the channel structure 160 and the bit line contact 170.

However, according to some embodiments described above, the bit line 180 may be formed by a patterning process using EUV exposure. The bit line 180 may include the first bending portion 180B1, so that the bit line 180 may be disposed on the central portion of the channel structure 160 without forming an additional stud. The semiconductor device 100 may have a relatively low electrical resistance between the bit line 180 and the channel structure 160, thereby providing excellent electrical characteristics.

In a channel layer made of a typical semiconductor material such as, for example, polysilicon, problems such as a reduction of on current, deterioration of swing, an increase in leakage current, a change in operating characteristics over temperature, or a Vt fluctuation may occur due to a grain boundary effect. However, when the semiconductor device 100 according to embodiments includes the channel layer 164 made of an oxide semiconductor material, these problems may not occur. In addition, the channel layer 164 made of an oxide semiconductor material may have characteristics of high mobility, low leakage current, low subthreshold swing, and good uniformity at a low temperature. Accordingly, the semiconductor device 100 according to embodiments may have excellent electrical characteristics and may be manufactured in a low-temperature process.

Also, the channel layer 164 included in the semiconductor device 100 according to embodiment may have a stacked structure of the first oxide semiconductor channel layer 164N and the second oxide semiconductor channel layer 164P. Sufficient electrons may be supplied to the first oxide semiconductor channel layer 164N, and sufficient holes may be supplied to the second oxide semiconductor channel layer 164P. Accordingly, carriers desired for each of read, program, and erase operations may be sufficiently supplied to the channel layer 164, and thus, the operating speed of the semiconductor device 100 may be improved.

In addition, the channel layer 164 included in the semiconductor device 100 according embodiments may form, on the sidewall of the channel hole 160H, the second thickness T2 of the second oxide semiconductor channel layer 164P for supplying holes for an erase operation to be smaller than the first thickness T1 of the first oxide semiconductor channel layer 164N for supplying electrons for a read operation and a program operation requiring a relatively high speed. Thus, a channel layer 164 of a relatively small thickness may be formed on the sidewall of channel hole 160H. Accordingly, the degree of integration of the semiconductor device 100 may be improved.

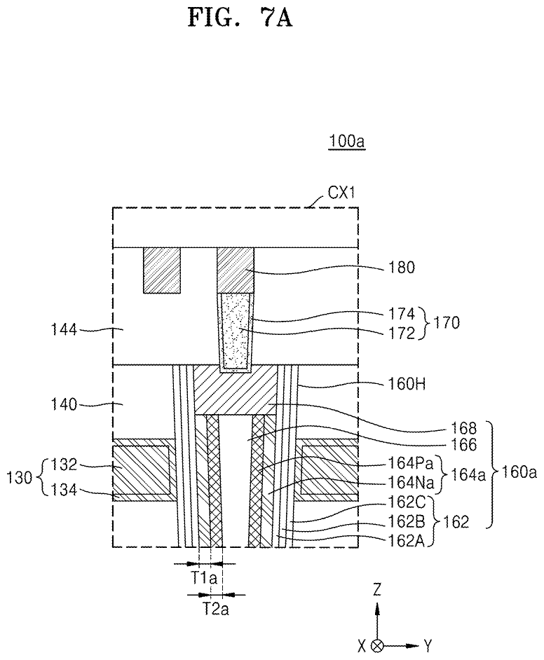

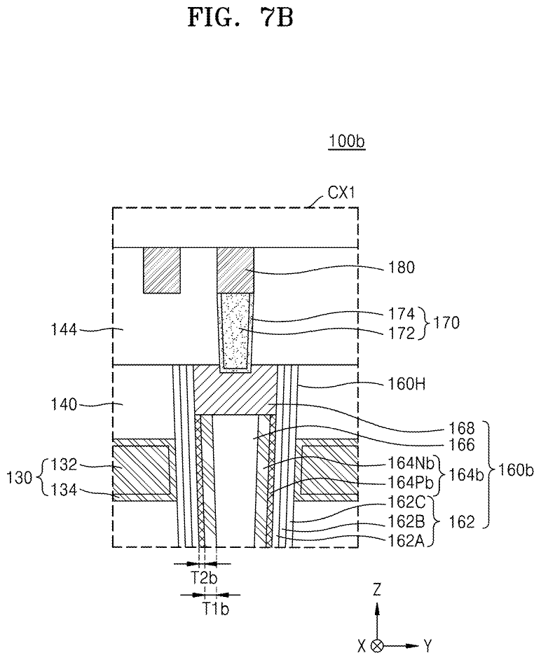

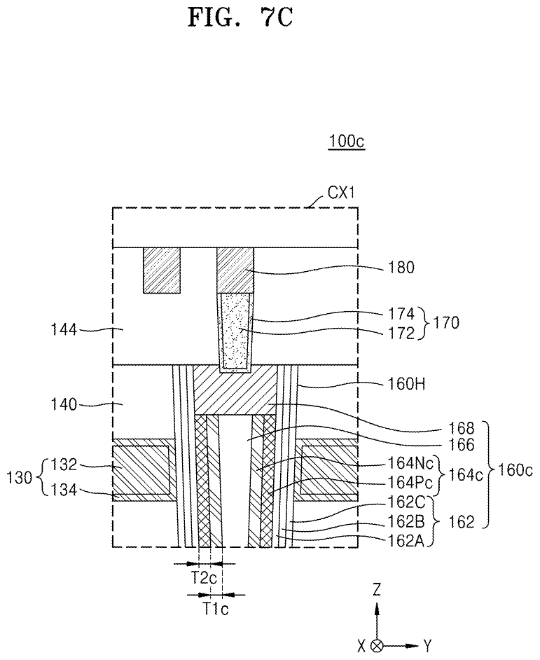

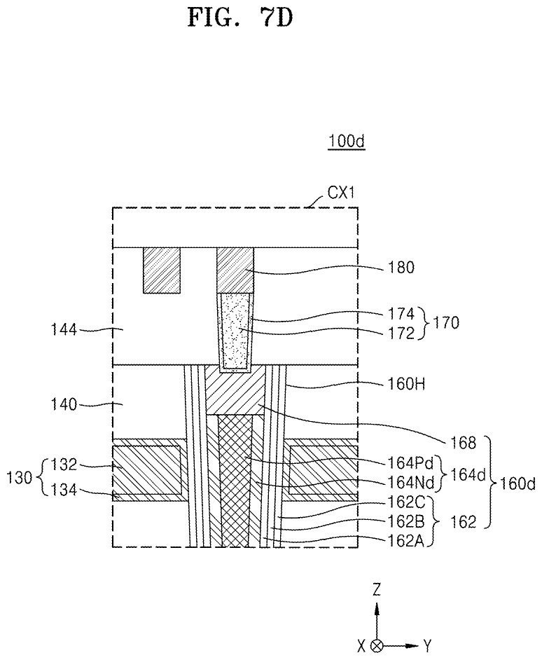

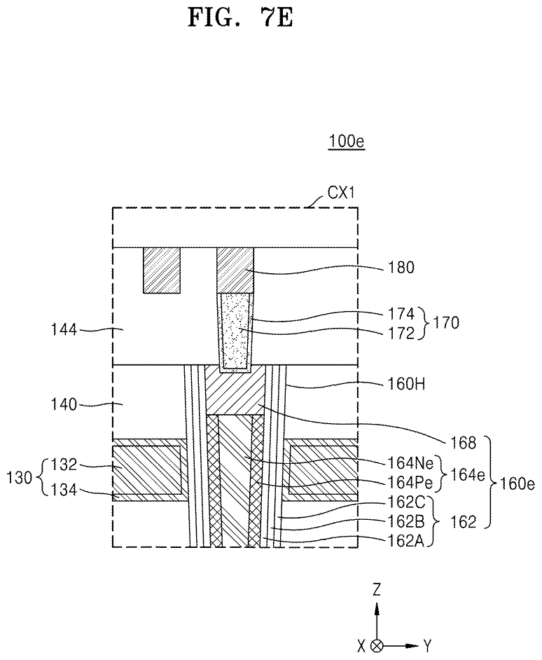

FIGS. 7A to 7E are enlarged cross-sectional views of semiconductor devices according to some embodiments. Specifically, FIGS. 7A to 7E are enlarged views of portions corresponding to the portion CX1 of FIG. 4, the same member numerals as those of FIGS. 3 to 6 denote the same members, and redundant descriptions with those of FIGS. 3 to 6 will not be repeated.

Referring to FIG. 7A, a semiconductor device 100a may include a channel structure 160a disposed in the channel hole 160H. The semiconductor device 100a shown in FIG. 7A may include the channel structure 160a instead of the channel structure 160 included in the semiconductor device 100 shown in FIGS. 3 to 6. Each of a plurality of channel structures 160a may include the gate insulating layer 162, a channel layer 164a, the buried insulating layer 166, and the conductive plug 168. The gate insulating layer 162 and the channel layer 164a may be sequentially disposed on the sidewall of the channel hole 160H. For example, the gate insulating layer 162 may be conformally disposed on the sidewall of the channel hole 160H, and the channel layer 164a may be conformally disposed on the sidewall and bottom portion of the channel hole 160H. The conductive plug 168 contacting the channel layer 164a and blocking an entrance of the channel hole 160H may be disposed on the upper side of the channel hole 160H. In some embodiments, the buried insulating layer 166 filling a part of the channel hole 160H may be disposed on the channel layer 164a, and the conductive plug 168 may contact the channel layer 164a and the buried insulating layer 166 and fill the upper side of the channel hole 160H. For example, the buried insulating layer 166 may fill a space defined by the channel layer 164a in the channel hole 160H.

In some embodiments, the channel layer 164a may be disposed to contact the upper surface of the substrate 110 on the bottom portion of the channel hole 160H. In some other embodiments, a contact semiconductor layer (not shown) having a certain height on the substrate 110 may be further formed on the bottom portion of the channel hole 160H, and the channel layer 164a may be electrically connected to the substrate 110 through the contact semiconductor layer.

The channel layer 164a may be made of an oxide semiconductor material. The channel layer 164a may also be referred to as an oxide semiconductor channel layer. The channel layer 164a may include at least one oxide semiconductor material of a binary or ternary oxide semiconductor material including a first metal element, a ternary oxide semiconductor material including a first metal element and a second metal element different from each other, a quaternary oxide semiconductor material including a first metal element, a second metal element, and a third metal element different from each other, or a quinary oxide semiconductor material including a first metal element, a second metal element, a third metal element, and a fourth metal element different from each other.

In some embodiments, the channel layer 164a may include at least one crystallinity of amorphous, single crystalline, polycrystalline, spinel, or CAAC.

The channel layer 164a may have a stacked structure of a first oxide semiconductor channel layer 164Na and a second oxide semiconductor channel layer 164Pa. The gate insulating layer 162, the first oxide semiconductor channel layer 164Na, and the second oxide semiconductor channel layer 164Pa may be sequentially disposed on the sidewall of the channel hole 160H. The first oxide semiconductor channel layer 164Na and the second oxide semiconductor channel layer 164Pa may be sequentially disposed on the bottom portion of the channel hole 160H. For example, the first oxide semiconductor channel layer 164Na may conformally cover the gate insulating layer 162 covering the sidewall of the channel hole 160H and the bottom portion of the channel hole 160H, and the second oxide semiconductor channel layer 164Pa may conformally cover the first oxide semiconductor channel layer 164Na covering the sidewall of the channel hole 160H and the bottom portion of the channel hole 160H.

The first oxide semiconductor channel layer 164Na and the second oxide semiconductor channel layer 164Pa may have different conductivity types. The first oxide semiconductor channel layer 164Na may have a first conductivity type, and the second oxide semiconductor channel layer 164Pa may have a second conductivity type different from the first conductivity type. For example, the first conductivity type may be an n-type, the second conductivity type may be a p-type, the first oxide semiconductor channel layer 164Na may be referred to as an n-type oxide semiconductor channel layer, and the second oxide semiconductor channel layer 164Pa may be referred to as a p-type oxide semiconductor channel layer.

On the sidewall of the channel hole 160H, the first oxide semiconductor channel layer 164Na may have a first thickness T1a, and the second oxide semiconductor channel layer 164Pa may have a second thickness T2a. In some embodiments, the first thickness T1a and the second thickness T2a may be substantially the same. For example, each of the first thickness T1a and the second thickness T2a may be about 30 Å to about 100 Å.

In some embodiments, the first oxide semiconductor channel layer 164Na and the second oxide semiconductor channel layer 164Pa may include at least one same metal element. In some embodiments, a band gap of a material constituting the first oxide semiconductor channel layer 164Na may have a greater value than that of a band gap of a material constituting the second oxide semiconductor channel layer 164Pa.

As shown in FIG. 7A, the gate insulating layer 162 may have a structure including the tunneling dielectric layer 162A, the charge storage layer 162B, and the blocking dielectric layer 162C sequentially disposed on the outer wall of the channel layer 164a.

Referring to FIG. 7B, a semiconductor device 100b may include a channel structure 160b disposed in the channel hole 160H. The semiconductor device 100b shown in FIG. 7B may include the channel structure 160b instead of the channel structure 160 included in the semiconductor device 100 shown in FIGS. 3 to 6. Each of a plurality of channel structures 160b may include the gate insulating layer 162, a channel layer 164b, the buried insulating layer 166, and the conductive plug 168. The gate insulating layer 162 and the channel layer 164b may be sequentially disposed on the sidewall of the channel hole 160H. For example, the gate insulating layer 162 may be conformally disposed on the sidewall of the channel hole 160H, and the channel layer 164b may be conformally disposed on the sidewall and bottom portion of the channel hole 160H. The conductive plug 168 contacting the channel layer 164b and blocking an entrance of the channel hole 160H may be disposed on the upper side of the channel hole 160H. In some embodiments, the buried insulating layer 166 filling a part of the channel hole 160H may be disposed on the channel layer 164b, and the conductive plug 168 may contact the channel layer 164b and the buried insulating layer 166 and fill the upper side of the channel hole 160H. For example, the buried insulating layer 166 may fill a space defined by the channel layer 164b in the channel hole 160H.

In some embodiments, the channel layer 164b may be disposed to contact the upper surface of the substrate 110 on the bottom portion of the channel hole 160H. In some other embodiments, a contact semiconductor layer (not shown) having a certain height on the substrate 110 may be further formed on the bottom portion of the channel hole 160H, and the channel layer 164b may be electrically connected to the substrate 110 through the contact semiconductor layer.

The channel layer 164b may be made of an oxide semiconductor material. The channel layer 164b may also be referred to as an oxide semiconductor channel layer.

The channel layer 164b may have a stacked structure of a first oxide semiconductor channel layer 164Pb and a second oxide semiconductor channel layer 164Nb. The gate insulating layer 162, the first oxide semiconductor channel layer 164Pb, and the second oxide semiconductor channel layer 164Nb may be sequentially disposed on the sidewall of the channel hole 160H. The first oxide semiconductor channel layer 164Pb and the second oxide semiconductor channel layer 164Nb may be sequentially disposed on the bottom portion of the channel hole 160H. For example, the first oxide semiconductor channel layer 164Pb may conformally cover the gate insulating layer 162 covering the sidewall of the channel hole 160H and the bottom portion of the channel hole 160H, and the second oxide semiconductor channel layer 164Nb may conformally cover the first oxide semiconductor channel layer 164Pb covering the sidewall of the channel hole 160H and the bottom portion of the channel hole 160H.

The first oxide semiconductor channel layer 164Pb and the second oxide semiconductor channel layer 164Nb may have different conductivity types. The first oxide semiconductor channel layer 164Pb may have a second conductivity type, and the second oxide semiconductor channel layer 164Nb may have a first conductivity type different from the second conductivity type. For example, the first conductivity type may be an n-type and the second conductivity type may be a p-type. The first oxide semiconductor channel layer 164Pb may be referred to as a p-type oxide semiconductor channel layer, and the second oxide semiconductor channel layer 164Nb may be referred to as an n-type oxide semiconductor channel layer.

On the sidewall of the channel hole 160H, the first oxide semiconductor channel layer 164Pb may have a second thickness T2b, and the second oxide semiconductor channel layer 164Nb may have a first thickness T1b. In some embodiments, the first thickness T1b may be greater than the second thickness T2b. For example, the first thickness T1b may be about 50 Å to about 100 Å, and the second thickness T2b may be about 30 Å to about 80 Å.

In some embodiments, the first oxide semiconductor channel layer 164Pb and the second oxide semiconductor channel layer 164Nb may include at least one of the same metal element. In some embodiments, a band gap of a material constituting the first oxide semiconductor channel layer 164Pb may have a smaller value than that of a band gap of a material constituting the second oxide semiconductor channel layer 164Nb.

As shown in FIG. 7B, the gate insulating layer 162 may have a structure including the tunneling dielectric layer 162A, the charge storage layer 162B, and the blocking dielectric layer 162C sequentially disposed on the outer wall of the channel layer 164b.

Referring to FIG. 7C, a semiconductor device 100c may include a channel structure 160c disposed in the channel hole 160H. The semiconductor device 100c shown in FIG. 7C may include the channel structure 160c instead of the channel structure 160 that is included in the semiconductor device 100 shown in FIGS. 3 to 6. Each of the plurality of channel structures 160c may include the gate insulating layer 162, a channel layer 164c, the buried insulating layer 166, and the conductive plug 168. The gate insulating layer 162 and the channel layer 164c may be sequentially disposed on the sidewall of the channel hole 160H. For example, the gate insulating layer 162 may be conformally disposed on the sidewall of the channel hole 160H, and the channel layer 164c may be conformally disposed on the sidewall and bottom portion of the channel hole 160H. The conductive plug 168 contacting the channel layer 164c and blocking an entrance of the channel hole 160H may be disposed on the upper side of the channel hole 160H. In some embodiments, the buried insulating layer 166 filling a part of the channel hole 160H may be disposed on the channel layer 164c, and the conductive plug 168 may contact the channel layer 164c and the buried insulating layer 166 and fill the upper side of the channel hole 160H. For example, the buried insulating layer 166 may fill a space defined by the channel layer 164c in the channel hole 160H.

In some embodiments, the channel layer 164c may be disposed to contact the upper surface of the substrate 110 on the bottom portion of the channel hole 160H. In some other embodiments, a contact semiconductor layer (not shown) having a certain height on the substrate 110 may be further formed on the bottom portion of the channel hole 160H, and the channel layer 164c may be electrically connected to the substrate 110 through the contact semiconductor layer.

The channel layer 164c may be made of an oxide semiconductor material. The channel layer 164c may also be referred to as an oxide semiconductor channel layer.

The channel layer 164c may have a stacked structure of a first oxide semiconductor channel layer 164Pc and a second oxide semiconductor channel layer 164Nc. The gate insulating layer 162, the first oxide semiconductor channel layer 164Pc, and the second oxide semiconductor channel layer 164Nc may be sequentially disposed on the sidewall of the channel hole 160H. The first oxide semiconductor channel layer 164Pc and the second oxide semiconductor channel layer 164Nc may be sequentially disposed on the bottom portion of the channel hole 160H. For example, the first oxide semiconductor channel layer 164Pc may conformally cover the gate insulating layer 162 covering the sidewall of the channel hole 160H and the bottom portion of the channel hole 160H, and the second oxide semiconductor channel layer 164Nc may conformally cover the first oxide semiconductor channel layer 164Pc covering the sidewall of the channel hole 160H and the bottom portion of the channel hole 160H.

The first oxide semiconductor channel layer 164Pc and the second oxide semiconductor channel layer 164Nc may have different conductivity types. The first oxide semiconductor channel layer 164Pc may have a second conductivity type, and the second oxide semiconductor channel layer 164Nc may have a first conductivity type different from the second conductivity type. For example, the first conductivity type may be an n-type, the second conductivity type may be a p-type, the first oxide semiconductor channel layer 164Pc may be referred to as a p-type oxide semiconductor channel layer, and the second oxide semiconductor channel layer 164Nc may be referred to as an n-type oxide semiconductor channel layer.

On the sidewall of the channel hole 160H, the first oxide semiconductor channel layer 164Pc may have a second thickness T2c, and the second oxide semiconductor channel layer 164Nc may have a first thickness T1c. In some embodiments, the first thickness T1c and the second thickness T2c may be substantially the same. For example, each of the first thickness T1c and the second thickness T2c may be about 30 Å to about 100 Å.

In some embodiments, the first oxide semiconductor channel layer 164Pc and the second oxide semiconductor channel layer 164Nc may include at least one of a same metal element. In some embodiments, a bandgap of a material constituting the first oxide semiconductor channel layer 164Pc may have a smaller value than that of a bandgap of a material constituting the second oxide semiconductor channel layer 164Nc.

As shown in FIG. 7C, the gate insulating layer 162 may have a structure including the tunneling dielectric layer 162A, the charge storage layer 162B, and the blocking dielectric layer 162C sequentially disposed on the outer wall of the channel layer 164c.

Referring to FIG. 7D, a semiconductor device 100d may include a channel structure 160d disposed in the channel hole 160H. The semiconductor device 100d shown in FIG. 7D may include a channel structure 160d instead of the channel structure 160 included in the semiconductor device 100 shown in FIGS. 3 to 6. Each of the plurality of channel structures 160d may include the gate insulating layer 162, a channel layer 164d, and the conductive plug 168. The gate insulating layer 162 and the channel layer 164d may be sequentially disposed on the sidewall of the channel hole 160H. For example, the gate insulating layer 162 may be conformally disposed on the sidewall of the channel hole 160H, and the channel layer 164d may fill a part of the channel hole 160H. The conductive plug 168 contacting the channel layer 164d and blocking an entrance of the channel hole 160H may be disposed on the upper side of the channel hole 160H. The channel structure 160d shown in FIG. 7D may not include the buried insulating layer 166 included in each of the channel structures 160, 160a, 160b, and 160c shown in FIGS. 6 to 7C. For example, a space corresponding to the buried insulating layer 166 included in each of the channel structures 160, 160a, 160b, and 160c shown in FIGS. 6 to 7C may be filled with a part of the channel structure 160d shown in FIG. 7D. That is, the channel layer 164d may fill at least a part of the space defined by the gate insulating layer 162 in the channel hole 160H. The conductive plug 168 may contact the channel layer 164d and the buried insulating layer 166 and fill the upper side of the channel hole 160H. As an example, the channel layer 164d may completely fill the lower side of the space defined by the gate insulating layer 162 in the channel hole 160H, except for the upper side where the conductive plug 168 is disposed. The channel layer 164d may be formed in a pillar shape.

In some embodiments, the channel layer 164d may be disposed to contact the upper surface of the substrate 110 on the bottom portion of the channel hole 160H. In some other embodiments, a contact semiconductor layer (not shown) having a certain height on the substrate 110 may be further formed on the bottom portion of the channel hole 160H, and the channel layer 164d may be electrically connected to the substrate 110 through the contact semiconductor layer.

The channel layer 164d may be made of an oxide semiconductor material. The channel layer 164d may also be referred to as an oxide semiconductor channel layer.

The channel layer 164d may have a stacked structure of a first oxide semiconductor channel layer 164Nd and a second oxide semiconductor channel layer 164Pd. The gate insulating layer 162, the first oxide semiconductor channel layer 164Nd, and the second oxide semiconductor channel layer 164Pd may be sequentially disposed on the sidewall of the channel hole 160H. The first oxide semiconductor channel layer 164Nd and the second oxide semiconductor channel layer 164Pd may be sequentially disposed on the bottom portion of the channel hole 160H. For example, the first oxide semiconductor channel layer 164Nd may conformally cover the gate insulating layer 162 covering the sidewall of the channel hole 160H and the bottom portion of the channel hole 160H, and the second oxide semiconductor channel layer 164Pd may fill a space limited by the first oxide semiconductor channel layer 164Nd.

When at least a part of the space defined by the gate insulating layer 162 in the channel hole 160H is filled with a channel layer, and the channel layer is made of a common semiconductor material, for example, polysilicon, a void or seam may be formed in the channel hole 160H. However, when the channel layer 164d included in the semiconductor device 100d according to embodiments is made of an oxide semiconductor material, no void or seam may be formed in the channel hole 160H. Accordingly, in the semiconductor device 100d according to embodiments, the channel structure 160d does not include the buried insulating layer 166 included in each of the channel structures 160, 160a, 160b, and 160c shown in FIGS. 6 to 7C, and thus, horizontal widths of the channel hole 160H and the channel structure 160d may be reduced.

The first oxide semiconductor channel layer 164Nd and the second oxide semiconductor channel layer 164Pd may have different conductivity types. The first oxide semiconductor channel layer 164Nd may have a first conductivity type, and the second oxide semiconductor channel layer 164Pd may have a second conductivity type different from the first conductivity type. For example, the first conductivity type may be an n-type, the second conductivity type may be a p-type, the first oxide semiconductor channel layer 164Nd may be referred to as an n-type oxide semiconductor channel layer, and the second oxide semiconductor channel layer 164Pd may be referred to as a p-type oxide semiconductor channel layer.

In some embodiments, the first oxide semiconductor channel layer 164Nd and the second oxide semiconductor channel layer 164Pd may include at least one same metal element. In some embodiments, a bandgap of a material constituting the first oxide semiconductor channel layer 164Nd may have a greater value than that of a bandgap of a material constituting the second oxide semiconductor channel layer 164Pd.

As shown in FIG. 7D, the gate insulating layer 162 may have a structure including the tunneling dielectric layer 162A, the charge storage layer 162B, and the blocking dielectric layer 162C sequentially disposed on the outer wall of the channel layer 164d.

FIG. 7D shows that, on the sidewall of the channel hole 160H, the thickness of the second oxide semiconductor channel layer 164Pd is greater than the thickness of the first oxide semiconductor channel layer 164Nd. However, the recited thicknesses are an example and the embodiments are not limited thereto. The thickness of the second oxide semiconductor channel layer 164Pd may vary depending on the horizontal width of the channel hole 160H. For example, when the horizontal width of the channel hole 160H is relatively large, the thickness of the second oxide semiconductor channel layer 164Pd may be greater than the thickness of the first oxide semiconductor channel layer 164Nd. In addition, when the horizontal width of the channel hole 160H is relatively small, the thickness of the second oxide semiconductor channel layer 164Pd may be smaller than the thickness of the first oxide semiconductor channel layer 164Nd.

Accordingly, the semiconductor device 100d according to embodiments may reduce the horizontal widths of the channel hole 160H and the channel structure 160d, and thus, the degree of integration thereof may be improved.

Referring to FIG. 7E, a semiconductor device 100e may include a channel structure 160e disposed in the channel hole 160H. The semiconductor device 100e shown in FIG. 7E may include the channel structure 160e instead of the channel structure 160 included in the semiconductor device 100 shown in FIGS. 3 to 6. Each of a plurality of channel structures 160e may include the gate insulating layer 162, a channel layer 164e, and the conductive plug 168. The gate insulating layer 162 and the channel layer 164e may be sequentially disposed on the sidewall of the channel hole 160H. For example, the gate insulating layer 162 may be conformally disposed on the sidewall of the channel hole 160H, and the channel layer 164e may fill a part of the channel hole 160H. The conductive plug 168 contacting the channel layer 164e and blocking an entrance of the channel hole 160H may be disposed on the upper side of the channel hole 160H. The channel structure 160e shown in FIG. 7E might not include the buried insulating layer 166 included in each of the channel structures 160, 160a, 160b, and 160c shown in FIGS. 6 to 7C. The channel layer 164e may fill at least a part of the space defined by the gate insulating layer 162 in the channel hole 160H. The conductive plug 168 may contact the channel layer 164e and the buried insulating layer 166 and fill an upper side of the channel hole 160H. For example, the channel layer 164e may completely fill the lower side of the space defined by the gate insulating layer 162 in the channel hole 160H, except for the upper side where the conductive plug 168 is disposed. The channel layer 164e may be formed in a pillar shape.

In some embodiments, the channel layer 164e may be disposed to contact the upper surface of the substrate 110 on the bottom portion of the channel hole 160H. In some other embodiments, a contact semiconductor layer (not shown) having a certain height on the substrate 110 may be further formed on the bottom portion of the channel hole 160H, and the channel layer 164e may be electrically connected to the substrate 110 through the contact semiconductor layer.

The channel layer 164e may be made of an oxide semiconductor material. The channel layer 164e may also be referred to as an oxide semiconductor channel layer.

The channel layer 164e may have a stacked structure of a first oxide semiconductor channel layer 164Pe and a second oxide semiconductor channel layer 164Ne. The gate insulating layer 162, the first oxide semiconductor channel layer 164Pe, and the second oxide semiconductor channel layer 164Ne may be sequentially disposed on the sidewall of the channel hole 160H. The first oxide semiconductor channel layer 164Pe and the second oxide semiconductor channel layer 164Ne may be sequentially disposed on the bottom portion of the channel hole 160H. For example, the first oxide semiconductor channel layer 164Pe may conformally cover the gate insulating layer 162 covering the sidewall of the channel hole 160H and the bottom portion of the channel hole 160H, and the second oxide semiconductor channel layer 164Ne may fill a space limited by the first oxide semiconductor channel layer 164Pe.

The first oxide semiconductor channel layer 164Pe and the second oxide semiconductor channel layer 164Ne may have different conductivity types. The first oxide semiconductor channel layer 164Pe may have a second conductivity type, and the second oxide semiconductor channel layer 164Ne may have a first conductivity type different from the second conductivity type. For example, the first conductivity type may be an n-type, the second conductivity type may be a p-type. The first oxide semiconductor channel layer 164Pe may be referred to as a p-type oxide semiconductor channel layer, and the second oxide semiconductor channel layer 164Ne may be referred to as an n-type oxide semiconductor channel layer.

In some embodiments, the first oxide semiconductor channel layer 164Pe and the second oxide semiconductor channel layer 164Ne may include at least one same metal element. In some embodiments, a band gap of a material constituting the first oxide semiconductor channel layer 164Pe may have a smaller value than a band gap of a material constituting the second oxide semiconductor channel layer 164Ne.

As shown in FIG. 7E, the gate insulating layer 162 may have a structure including the tunneling dielectric layer 162A, the charge storage layer 162B, and the blocking dielectric layer 162C sequentially disposed on the outer wall of the channel layer 164e.

FIG. 7E shows that, on the sidewall of the channel hole 160H, the thickness of the second oxide semiconductor channel layer 164Ne is greater than the thickness of the first oxide semiconductor channel layer 164Pe, however, the thicknesses that are shown or described are examples and embodiments are not limited thereto. The thickness of the second oxide semiconductor channel layer 164Ne may vary depending on the horizontal width of the channel hole 160H. For example, when the horizontal width of the channel hole 160H is relatively large, the thickness of the second oxide semiconductor channel layer 164Ne may be greater than the thickness of the first oxide semiconductor channel layer 164Pe. When the horizontal width of the channel hole 160H is relatively small, the thickness of the second oxide semiconductor channel layer 164Ne may be less than the thickness of the first oxide semiconductor channel layer 164Pe.

Accordingly, the semiconductor device 100e according to embodiments may reduce the horizontal widths of the channel hole 160H and the channel structure 160e, and thus, the degree of integration thereof may be improved.

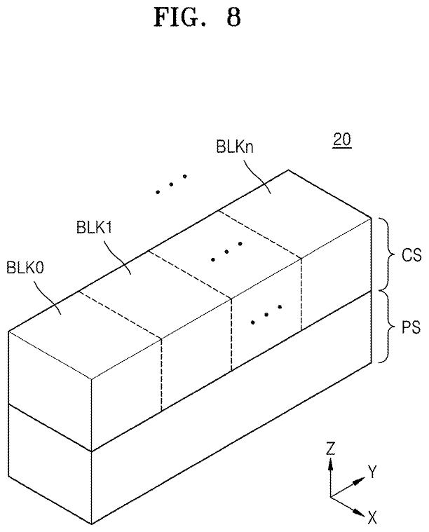

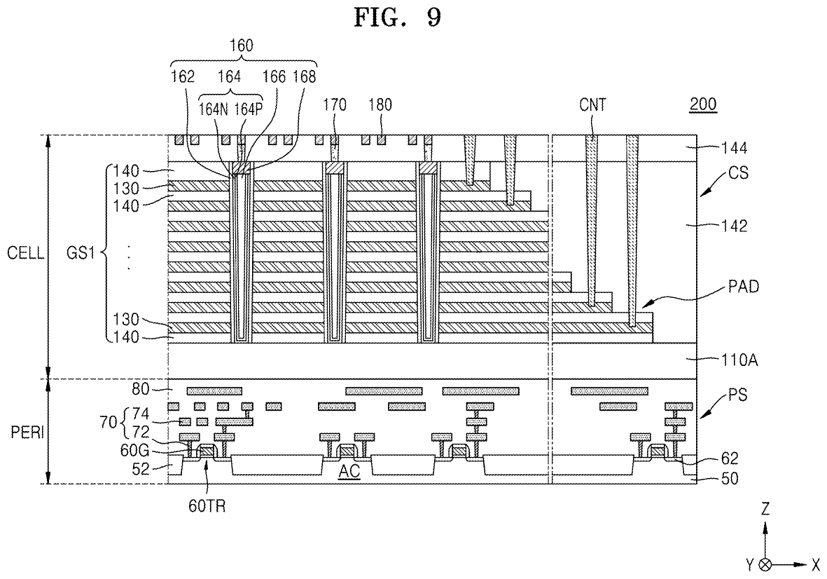

FIG. 8 is a perspective view of a semiconductor device according to some embodiments, and FIG. 9 is a cross-sectional view of the semiconductor device of FIG. 8. In FIGS. 8 and 9, the same reference numerals as in FIGS. 1 to 7E denote the same components.

Referring to FIGS. 8 and 9 together, a semiconductor device 200 includes a cell array structure CS and a peripheral circuit structure PS that overlap each other in a vertical direction (Z direction). The cell array structure CS may include the memory cell array 20 described with reference to FIG. 1. The peripheral circuit structure PS may include the peripheral circuit 30 described with reference to FIG. 1.

The cell array structure CS may include the plurality of memory cell blocks BLK1, BLK2, . . . , BLKn. Each of the plurality of memory cell blocks BLK1, BLK2, . . . , BLKn may include three-dimensionally arranged memory cells. The cell array structure CS may include a cell region CELL. The cell region CELL may include the memory cell region MCR and the connection region CON described with reference to FIGS. 3 to 7E. The peripheral circuit structure PS may include the peripheral circuit region PERI. Although not shown, the cell region CELL may include a through electrode region in which a plurality of through electrodes (not shown) for electrical connection between the memory cell region MCR and the peripheral circuit region PERI disposed at a lower vertical level than the memory cell region MCR are disposed. The through electrode region may be formed in a boundary between the memory cell region MCR and the connection region CON, or inside the connection region CON.

The peripheral circuit structure PS may include a peripheral circuit transistor 60TR and a peripheral circuit wiring structure 70 disposed on a substrate 50. The active region AC may be defined on the substrate 50 by a device isolation layer 52. The plurality of peripheral circuit transistors 60TR may be formed on the active region AC. The plurality of peripheral circuit transistors 60TR may include a peripheral circuit gate 60G and a source/drain region 62 disposed on a part of the substrate 50 on both sides of the peripheral circuit gate 60G.

The substrate 50 may include a semiconductor material such as a group IV semiconductor material, a group III-V semiconductor material, or a group II-VI semiconductor material. The group IV semiconductor material may include, for example, silicon (Si), germanium (Ge), or silicon-germanium (Si—Ge). The group III-V semiconductor material may include, for example, gallium arsenide (GaAs), indium phosphide (InP), gallium phosphide (GaP), indium arsenide (InAs), indium antimony (InSb), or indium gallium arsenide (InGaAs). The group II-VI semiconductor material may include, for example, zinc telluride (ZnTe) or cadmium sulfide (CdS). The substrate 50 may be a bulk wafer or an epitaxial layer. In some embodiments, the substrate 50 may include a SOI substrate or a GeOI substrate.

The peripheral circuit wiring structure 70 may include a plurality of peripheral circuit contacts 72 and a plurality of peripheral circuit wiring layers 74. An interlayer insulating layer 80 covering the peripheral circuit transistor 60TR and the peripheral circuit wiring structure 70 may be disposed on the substrate 50. The plurality of peripheral circuit wiring layers 74 may have a multilayer structure including a plurality of metal layers disposed at different vertical levels. FIG. 9 shows that all of the plurality of peripheral circuit wiring layers 74 are formed at the same height, but in some other embodiments, the peripheral circuit wiring layers 74 disposed at a level (e.g., disposed at the uppermost level) may be formed to a height greater than that of the peripheral circuit wiring layer 74 disposed at the remaining level.

A base structure 110A may be disposed on the interlayer insulating layer 80. In some embodiments, the base structure 110A may function as a source region supplying current to vertical memory cells formed in the cell array structure CS. In some embodiments, the base structure 110A may include some regions that perform the function of the common source line CSL described in FIG. 2.

In some embodiments, the base structure 110A may include a semiconductor material such as silicon (Si), germanium (Ge), or silicon-germanium. On the base structure 110A, the first gate stack GS1 may extend in the first horizontal direction (X direction) and the second horizontal direction (Y direction) parallel to the upper surface of the base structure 110A.

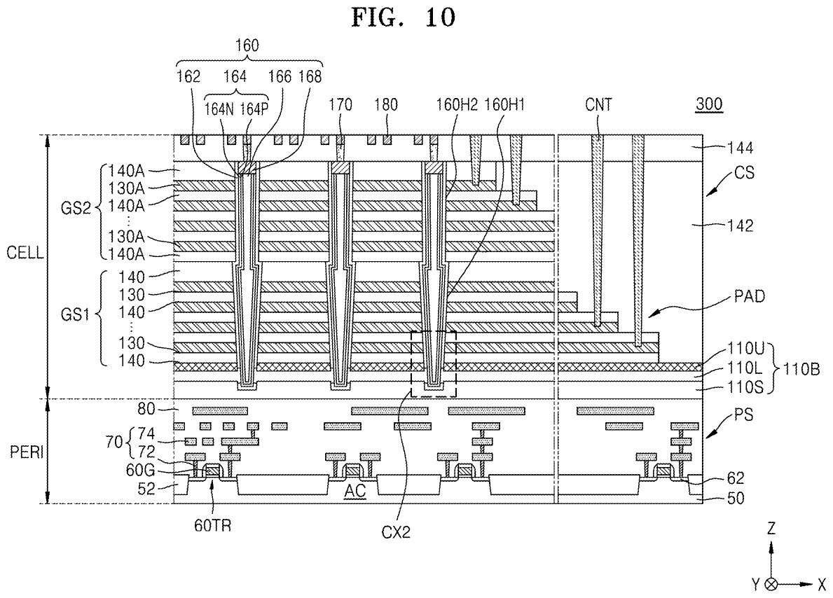

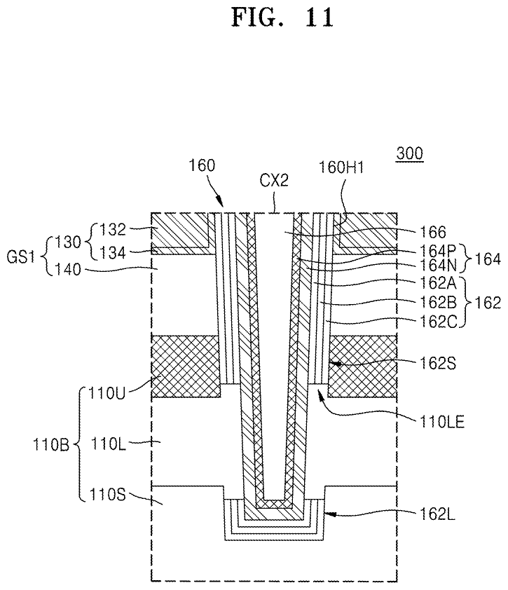

FIGS. 10 and 11 are diagrams illustrating a semiconductor device according to some embodiments. Specifically, FIG. 10 is a cross-sectional view of a semiconductor device according to some embodiments, and FIG. 11 is an enlarged cross-sectional view of a portion CX2 of FIG. 10.

Referring to FIGS. 10 and 11 together, a semiconductor device 300 may include the cell array structure CS and the peripheral circuit structure PS that overlap each other in the vertical direction (Z direction). The cell array structure CS may include the memory cell array 20 described with reference to FIG. 1. The peripheral circuit structure PS may include the peripheral circuit 30 described with reference to FIG. 1.

A base structure 110B may be disposed on the peripheral circuit structure PS. The base structure 110B may include a base substrate 110S, a lower base layer 110L, and an upper base layer 110U sequentially disposed on the interlayer insulating layer 80.

The base substrate 110S may include a semiconductor material such as silicon. The lower base layer 110L may include polysilicon doped with impurities or polysilicon undoped with impurities. The upper base layer 110U may include polysilicon doped with impurities or polysilicon undoped with impurities. The lower base layer 110L may correspond to the common source line CSL described with reference to FIG. 2. The upper base layer 110U may serve as a support layer to prevent a mold stack from collapsing or falling in a process of removing a sacrificial material layer (not shown) for forming the lower base layer 110L.

The first gate stack GS1 may be disposed on the base structure 110B. A second gate stack GS2 may be disposed on the first gate stack GS1. The first gate stack GS1 may include a plurality of first gate electrodes 130 and a plurality of first insulating layers 140 that are alternately disposed. The second gate stack GS2 may include a plurality of second gate electrodes 130A and a plurality of second insulating layers 140A that are alternately disposed.

Each of a plurality of channel structures 160 may be formed inside a first channel hole 160H1 penetrating the first gate stack GS1 and a second channel hole 160H2 penetrating the second gate stack GS2. Each of the plurality of channel structures 160 may have a shape protruding outward from the boundary between the first channel hole 160H1 and the second channel hole 160H2.

The plurality of channel structures 160 may penetrate the upper base layer 110U and the lower base layer 110L and contact the base substrate 110S. As shown in FIG. 11, a portion of the gate insulating layer 162 may be removed at the same level as the lower base layer 110L, and the channel layer 164 may contact an extension portion 110LE of the lower base layer 110L. A sidewall portion 162S and a bottom portion 162L of the gate insulating layer 162 may be spaced apart from each other with the extension portion 110LE of the lower base layer 110L disposed therebetween. The bottom portion 162L of the gate insulating layer 162 may surround the bottom surface of the channel layer 164, so that the channel layer 164 may be electrically connected to the lower base layer 110L instead of directly contacting the base substrate 110S. The channel layer 164 may have a stacked structure of the first oxide semiconductor channel layer 164N and the second oxide semiconductor channel layer 164P.

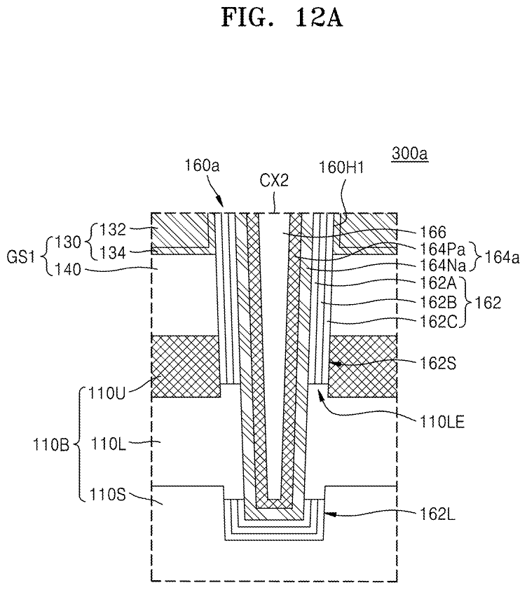

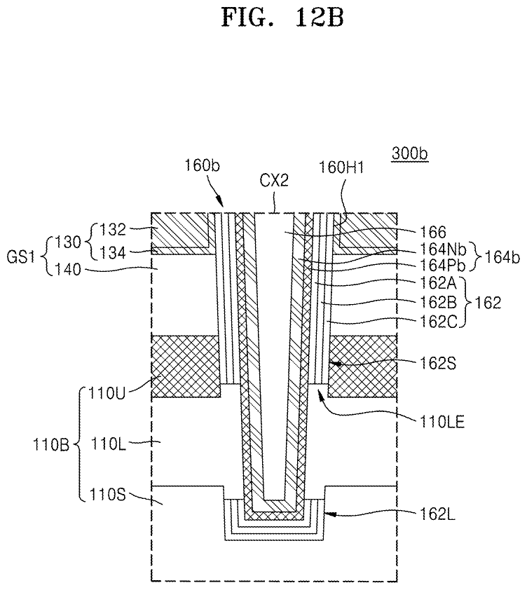

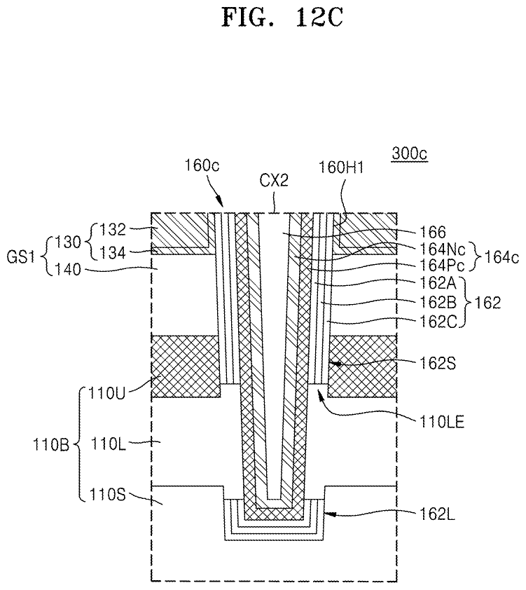

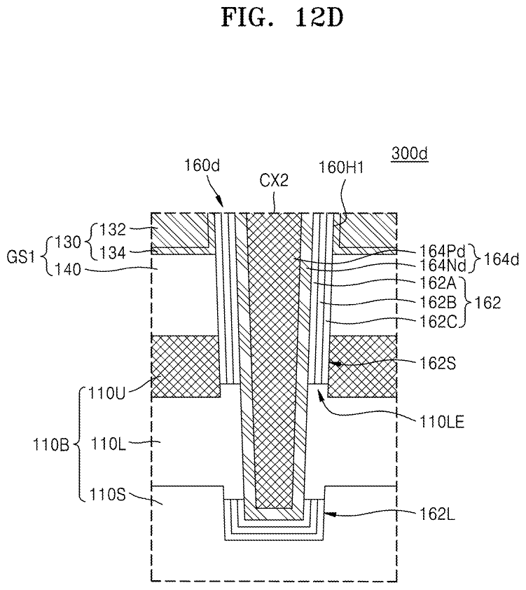

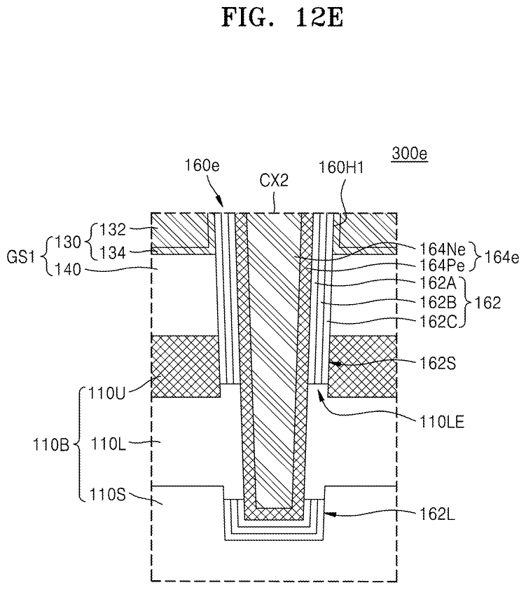

FIGS. 12A to 12E are enlarged cross-sectional views of semiconductor devices according to some embodiments. Specifically, FIGS. 12A to 12E are enlarged views of a portion corresponding to the portion CX2 of FIG. 10. The same member numerals as those of FIGS. 3 to 11 denote the same members, and redundant descriptions with those of FIGS. 3 to 11 will not be repeated.

Referring to FIG. 12A, a semiconductor device 300a may include the channel structure 160a disposed in the channel hole 160H. The semiconductor device 300a shown in FIG. 12A may include the channel structure 160a instead of the channel structure 160 included in the semiconductor device 300 shown in FIGS. 10 and 11. Each of the plurality of channel structures 160a may include the gate insulating layer 162, the channel layer 164a, the buried insulating layer 166, and the conductive plug 168. The channel layer 164a may have a stacked structure of the first oxide semiconductor channel layer 164Na and the second oxide semiconductor channel layer 164Pa.

Referring to FIG. 12B, a semiconductor device 300b may include the channel structure 160b disposed in the channel hole 160H. The semiconductor device 300b shown in FIG. 12B may include the channel structure 160b instead of the channel structure 160 included in the semiconductor device 300 shown in FIGS. 10 and 11. Each of the plurality of channel structures 160b may include the gate insulating layer 162, the channel layer 164b, the buried insulating layer 166, and the conductive plug 168. The channel layer 164b may have a stacked structure of the first oxide semiconductor channel layer 164Pb and the second oxide semiconductor channel layer 164Nb.

Referring to FIG. 12C, a semiconductor device 300c may include the channel structure 160c disposed in the channel hole 160H. The semiconductor device 100c shown in FIG. 12C may include the channel structure 160c instead of the channel structure 160 included in the semiconductor device 300 shown in FIGS. 10 and 11. Each of the plurality of channel structures 160c may include the gate insulating layer 162, the channel layer 164c, the buried insulating layer 166, and the conductive plug 168. The channel layer 164c may have a stacked structure of the first oxide semiconductor channel layer 164Pc and the second oxide semiconductor channel layer 164Nc.

Referring to FIG. 12D, a semiconductor device 300d may include the channel structure 160d disposed in the channel hole 160H. The semiconductor device 100d shown in FIG. 12D may include the channel structure 160d instead of the channel structure 160 included in the semiconductor device 300 shown in FIGS. 10 and 11. Each of the plurality of channel structures 160d may include the gate insulating layer 162, the channel layer 164d, and the conductive plug 168. The channel structure 160d shown in FIG. 12D may omit the buried insulating layer 166 included in each of the channel structures 160, 160a, 160b, and 160c shown in FIGS. 11 to 12C. The channel layer 164d may have a stacked structure of the first oxide semiconductor channel layer 164Nd and the second oxide semiconductor channel layer 164Pd.

Referring to FIG. 12E, a semiconductor device 300e may include the channel structure 160e disposed in the channel hole 160H. The semiconductor device 100e shown in FIG. 12E may include the channel structure 160e instead of the channel structure 160 included in the semiconductor device 300 shown in FIGS. 10 and 11. Each of the plurality of channel structures 160e may include the gate insulating layer 162, the channel layer 164e, and the conductive plug 168. The channel structure 160e shown in FIG. 12E may omit the buried insulating layer 166 included in each of the channel structures 160, 160a, 160b, and 160c shown in FIGS. 11 to 12c. The channel layer 164e may have a stacked structure of the first oxide semiconductor channel layer 164Pe and the second oxide semiconductor channel layer 164Ne.

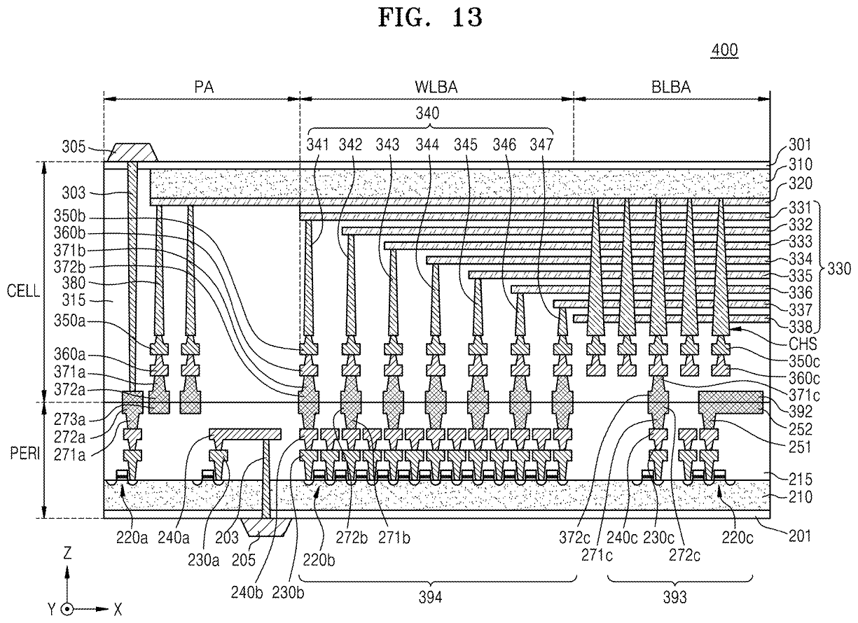

FIG. 13 is a diagram illustrating a semiconductor device 400 according to some embodiments. Referring to FIG. 13, a semiconductor device 400 may have a chip-to-chip (C2C) structure. The C2C structure may refer to a structure formed by manufacturing an upper chip including a cell region CELL on a first wafer, manufacturing a lower chip including a peripheral circuit region PERI on a second wafer, separate from the first wafer, and then bonding the upper chip and the lower chip to each other. The bonding process may include a method of electrically connecting a bonding metal formed on an uppermost metal layer of the upper chip and a bonding metal formed on an uppermost metal layer of the lower chip. For example, when the bonding metals may include copper (Cu) the upper chip and the lower chip may be bonded using a Cu-to-Cu bonding. In some implementations, the bonding metals may also be formed of other materials such as aluminum (A1) or tungsten (W).

Each of the peripheral circuit region PERI and the cell region CELL of the semiconductor device 400 may include an external pad bonding area PA, a word line bonding area WLBA, and a bit line bonding area BLBA.

The peripheral circuit region PERI may include a first substrate 210, an interlayer insulating layer 215, a plurality of circuit elements 220a, 220b, and 220c formed on the first substrate 210, first metal layers 230a, 230b, and 230c respectively connected to the plurality of circuit elements 220a, 220b, and 220c, and second metal layers 240a, 240b, and 240c formed on the first metal layers 230a, 230b, and 230c. In an embodiment, the first metal layers 230a, 230b, and 230c may be formed of tungsten, which has a relatively high electrical resistivity. The second metal layers 240a, 240b, and 240c may be formed of copper, which has a relatively low electrical resistivity.

In an embodiment illustrated in FIG. 13, although only the first metal layers 230a, 230b, and 230c and the second metal layers 240a, 240b, and 240c are shown and described, the embodiment is not limited thereto. One or more additional metal layers may be further formed on the second metal layers 240a, 240b, and 240c. At least a portion of the one or more additional metal layers formed on the second metal layers 240a, 240b, and 240c may be formed of aluminum etc. having a lower electrical resistivity than those of copper forming the second metal layers 240a, 240b, and 240c.

The interlayer insulating layer 215 may be disposed on the first substrate 210 and cover the plurality of circuit elements 220a, 220b, and 220c, the first metal layers 230a, 230b, and 230c, and the second metal layers 240a, 240b, and 240c. The interlayer insulating layer 215 may include an insulating material such as silicon oxide, silicon nitride, etc.

Lower bonding metals 271b and 272b may be formed on the second metal layer 240b in the word line bonding area WLBA. In the word line bonding area WLBA, the lower bonding metals 271b and 272b in the peripheral circuit region PERI may be electrically bonded to upper bonding metals 371b and 372b of the cell region CELL. The lower bonding metals 271b and 272b and the upper bonding metals 371b and 372b may be formed of aluminum, copper, tungsten, etc.

The cell region CELL may include at least one memory block. The cell region CELL may include a second substrate 310 and a common source line 320. On the second substrate 310, a plurality of word lines 331 to 338 (i.e., 330) may be stacked in a direction (a Z-axis direction), perpendicular to an upper surface of the second substrate 310. At least one string selection line and at least one ground selection line may be arranged on and below the plurality of word lines 330, respectively, and the plurality of word lines 330 may be disposed between the at least one string selection line and the at least one ground selection line.

In the bit line bonding area BLBA, a channel structure CHS may extend in a direction (a Z-axis direction), perpendicular to the upper surface of the second substrate 310, and pass through the plurality of word lines 330, the at least one string selection line, and the at least one ground selection line. The channel structure CHS may include a data storage layer, a channel layer, a buried insulating layer, etc. The channel layer may be electrically connected to a first metal layer 350c and a second metal layer 360c, e.g., a bit line. In an embodiment, the channel structure CHS may be formed in a shape similar to that of each of the channel structures 160, 160a, 160b, 160c, 160d, and 160e described with reference to FIGS. 3 to 12E.

In an embodiment illustrated in FIG. 13, an area in which the channel structure CHS, the bit line 360c, etc. are disposed may be defined as the bit line bonding area BLBA. In the bit line bonding area BLBA, the bit line 360c may be electrically connected to the circuit elements 220c providing a page buffer 393 in the peripheral circuit region PERI. The bit line 360c may be connected to upper bonding metals 371c and 372c in the cell region CELL, and the upper bonding metals 371c and 372c may be connected to lower bonding metals 271c and 272c connected to the circuit elements 220c of the page buffer 393.

In the word line bonding area WLBA, the plurality of word lines 330 may extend in a second direction (an X-axis direction), parallel to the upper surface of the second substrate 310 and perpendicular to the first direction, and may be connected to a plurality of cell contact plugs 341 to 347 (i.e., 340). The plurality of word lines 330 and the plurality of cell contact plugs 340 may be connected to each other in pads provided by at least a portion of the plurality of word lines 330 extending in different lengths in the second direction. A first metal layer 350b and a second metal layer 360b may be connected to an upper portion of the plurality of cell contact plugs 340 connected to the plurality of word lines 330, sequentially. The plurality of cell contact plugs 340 may be connected to the peripheral circuit region PERI by the upper bonding metals 371b and 372b of the cell region CELL and the lower bonding metals 271b and 272b of the peripheral circuit region PERI in the word line bonding area WLBA.

The plurality of cell contact plugs 340 may be electrically connected to the circuit elements 220b forming a row decoder 394 in the peripheral circuit region PERI. In an embodiment, operating voltages of the circuit elements 220b of the row decoder 394 may be different than operating voltages of the circuit elements 220c forming the page buffer 393. For example, operating voltages of the circuit elements 220c forming the page buffer 393 may be greater than operating voltages of the circuit elements 220b forming the row decoder 394.

A common source line contact plug 380 may be disposed in the external pad bonding area PA. The common source line contact plug 380 may be formed of a conductive material such as a metal, a metal compound, polysilicon, etc., and may be electrically connected to the common source line 320. A first metal layer 350a and a second metal layer 360a may be stacked on an upper portion of the common source line contact plug 380, sequentially. For example, an area in which the common source line contact plug 380, the first metal layer 350a, and the second metal layer 360a are disposed may be defined as the external pad bonding area PA.

Input-output pads 205 and 305 may be disposed in the external pad bonding area PA. Referring to FIG. 13, a lower insulating film 201 covering a lower surface of the first substrate 210 may be formed below the first substrate 210, and a first input-output pad 205 may be formed on the lower insulating film 201. The first input-output pad 205 may be connected to at least one of the plurality of circuit elements 220a, 220b, and 220c disposed in the peripheral circuit region PERI through a first input-output contact plug 203, and may be separated from the first substrate 210 by the lower insulating film 201. In addition, a side insulating film may be disposed between the first input-output contact plug 203 and the first substrate 210 to electrically separate the first input-output contact plug 203 and the first substrate 210.

Referring to FIG. 13, an upper insulating film 301 covering the upper surface of the second substrate 310 may be formed on the second substrate 310, and a second input-output pad 305 may be disposed on the upper insulating film 301. The second input-output pad 305 may be connected to at least one of the plurality of circuit elements 220a, 220b, and 220c disposed in the peripheral circuit region PERI through a second input-output contact plug 303. In the embodiment, the second input-output pad 305 is electrically connected to a circuit element 220a.

According to some embodiments, the second substrate 310 and the common source line 320 may not be disposed in an area in which the second input-output contact plug 303 is disposed. Also, the second input-output pad 305 may not overlap the word lines 330 in the third direction (the Z-axis direction). Referring to FIG. 13, the second input-output contact plug 303 may be separated from the second substrate 310 in a direction, parallel to the upper surface of the second substrate 310, and may pass through the interlayer insulating layer 315 of the cell region CELL to be connected to the second input-output pad 305.

According to some embodiments, the first input-output pad 205 and the second input-output pad 305 may be selectively formed. For example, the semiconductor device 400 may include only the first input-output pad 205 disposed on the first substrate 210 or the second input-output pad 305 disposed on the second substrate 310. Alternatively, the semiconductor device 400 may include both the first input-output pad 205 and the second input-output pad 305.

A metal pattern provided on an uppermost metal layer may be provided as a dummy pattern or the uppermost metal layer may be absent, in each of the external pad bonding area PA and the bit line bonding area BLBA, respectively included in the cell region CELL and the peripheral circuit region PERI.

In the external pad bonding area PA, the semiconductor device 400 may include a lower metal pattern 273a, corresponding to an upper metal pattern 372a formed in an uppermost metal layer of the cell region CELL, and having the same cross-sectional shape as the upper metal pattern 372a of the cell region CELL so as to be connected to each other, in an uppermost metal layer of the peripheral circuit region PERI. In the peripheral circuit region PERI, the lower metal pattern 273a formed in the uppermost metal layer of the peripheral circuit region PERI may not be connected to a contact. Similarly, in the external pad bonding area PA, an upper metal pattern 372a, corresponding to the lower metal pattern 273a formed in an uppermost metal layer of the peripheral circuit region PERI, and having the same shape as a lower metal pattern 273a of the peripheral circuit region PERI, may be formed in an uppermost metal layer of the cell region CELL.

The lower bonding metals 271b and 272b may be formed on the second metal layer 240b in the word line bonding area WLBA. In the word line bonding area WLBA, the lower bonding metals 271b and 272b of the peripheral circuit region PERI may be electrically connected to the upper bonding metals 371b and 372b of the cell region CELL by a Cu-to-Cu bonding.

Further, in the bit line bonding area BLBA, an upper metal pattern 392, corresponding to a lower metal pattern 252 formed in the uppermost metal layer of the peripheral circuit region PERI, and having the same cross-sectional shape as the lower metal pattern 252 of the peripheral circuit region PERI, may be formed in an uppermost metal layer of the cell region CELL. A contact may not be formed on the upper metal pattern 392 formed in the uppermost metal layer of the cell region CELL.

In an embodiment, corresponding to a metal pattern formed in an uppermost metal layer in one of the cell region CELL and the peripheral circuit region PERI, a reinforcement metal pattern having the same cross-sectional shape as the metal pattern may be formed in an uppermost metal layer in the other one of the cell region CELL and the peripheral circuit region PERI. A contact may not be formed on the reinforcement metal pattern.

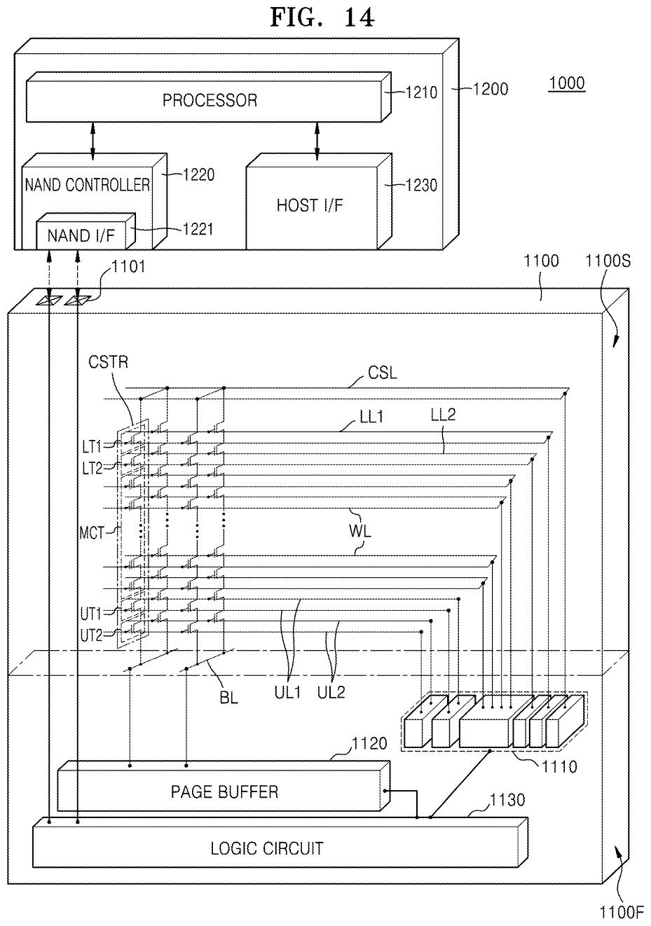

FIG. 14 is a schematic view of an electronic system 1000 including a semiconductor device 1100 according to some embodiments.

Referring to FIG. 14, an electronic system 1000 may include one or more semiconductor devices 1100, and a memory controller 1200 electrically connected to the semiconductor device 1100. The electronic system 1000 may, for example, include a solid state drive (SSD) device including at least one semiconductor device 1100, universal serial bus (USB), a computing system, a medical device, or a communication device.

The semiconductor device 1100 may include a non-volatile semiconductor device, and for example, the semiconductor device 1100 may include a NAND flash semiconductor device including one of the semiconductor devices 10, 100, 100a, 100b, 100c, 100d, 100e, 200, 300, 300a, 300b, 300c, 300d, 300e, and 400 described with reference to FIGS. 1 through 13. The semiconductor device 1100 may include a first structure 1100F and a second structure 1100S on the first structure 1100F. The first structure 1100F may include a periphery circuit structure including a row decoder 1110, a page buffer 1120, and a logic circuit 1130.

The second structure 1100S may have a memory cell structure including the bit line BL, the common source line CSL, the plurality of word lines WL, a first gate upper line UL1 and a second gate upper line UL2, a first ground selection line LL1 and a second ground selection line LL2, and a plurality of memory cell strings CSTR between the bit line BL and the common source line CSL.

In the second structure 1100S, each of the plurality of memory cell strings CSTR may include ground selection transistors LT1 and LT2 adjacent to the common source line CSL, and string selection transistors UT1 and UT2 adjacent to the bit line BL, and a plurality of memory cell transistors MCT arranged between the ground selection transistors LT1 and LT2 and the string selection transistors UT1 and UT2. The number of the ground selection transistors LT1 and LT2 and the number of the string selection transistors UT1 and UT2 may be variously modified according to some embodiments.

In some embodiments, the plurality of ground selection lines LL1 and LL2 may be connected to the ground selection transistors LT1 and LT2, respectively. The word line WL may be connected to a gate electrode of the memory cell transistor MCT. The plurality of string selection lines UL1 and UL2 may be connected to gate electrodes of string selection transistors UT1 and UT2, respectively.

The common source line CSL, the plurality of ground selection lines LL1 and LL2, the plurality of word lines WL, and the plurality of string selection lines UL1 and UL2 may be connected to the row decoder 1110. A plurality of bit lines BL may be electrically connected to the page buffer 1120.

The semiconductor device 1100 may communicate with a memory controller 1200 via an I/O pad 1101 electrically connected to the logic circuit 1130. The I/O pad 1101 may be electrically connected to the logic circuit 1130.

The memory controller 1200 may include a processor 1210, a NAND controller 1220, and a host interface 1230. In some embodiments, the electronic system 1000 may include a plurality of semiconductor devices 1100, and in this case, the memory controller 1200 may control the plurality of semiconductor devices 1100.

The processor 1210 may control the overall operation of the electronic system 1000 including the memory controller 1200. The processor 1210 may operate according to certain firmware, and may access the semiconductor device 1100 by controlling the NAND controller 1220. The NAND controller 1220 may include a NAND interface 1221, which processes communication with the semiconductor device 1100. Via the NAND interface 1221, a control command for controlling the semiconductor device 1100, data to be written to the plurality of memory cell transistors MCT of the semiconductor device 1100, data to be read from the plurality of memory cell transistors MCT of the semiconductor device 1100, etc. may be transmitted. The host interface 1230 may provide a communication function between the electronic system 1000 and an external host. When a control command is received from the external host via the host interface 1230, the processor 1210 may control the semiconductor device 1100 in response to the control command.

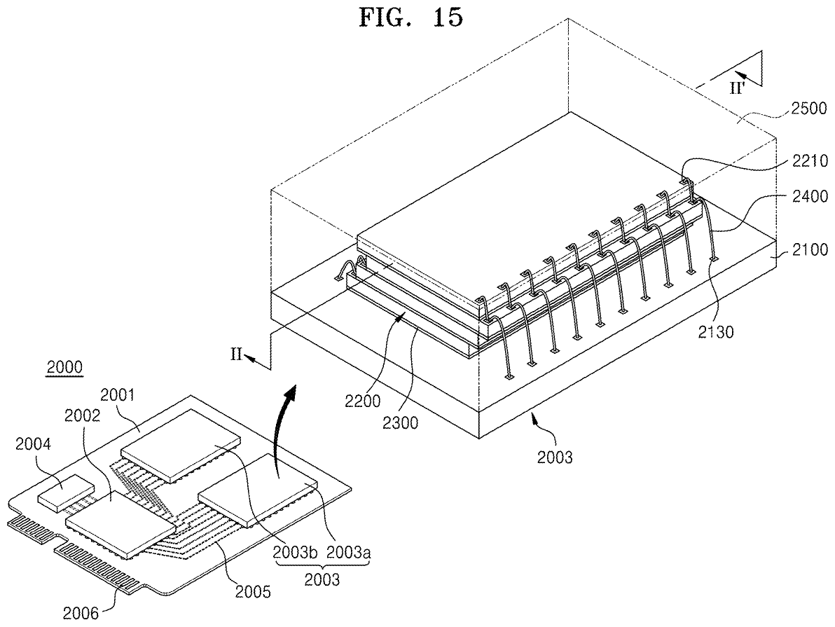

FIG. 15 is a schematic perspective view of an electronic system 2000 including a semiconductor device, according to some embodiments.

Referring to FIG. 15, the electronic system 2000 according to some embodiments may include a main substrate 2001, a controller 2002 mounted on the main substrate 2001, one or more semiconductor packages 2003, and a dynamic random access memory (DRAM) 2004. The semiconductor package 2003 and the DRAM 2004 may be connected to the controller 2002 by a plurality of distribution patterns 2005 formed on the main substrate 2001.

The main substrate 2001 may include a connector 2006 including a plurality of pins coupled with the external host. The number and an arrangement of the plurality of pins in the connector 2006 may vary according to a communication interface between the electronic system 2000 and the external host. In some embodiments, the electronic system 2000 may communicate with the external host according to any one of interfaces such as USB, peripheral component interconnect (PCI) express (PCI-E), serial advanced technology attachment (SATA), and M-Phy for a universal flash storage (UFS). In some embodiments, the electronic system 2000 may be operated by power supplied by the external host via the connector 2006. The electronic system 2000 may also further include a power management integrated circuit (PMIC), which distributes power supplied by the external host to the memory controller 2002 and the semiconductor package 2003.

The memory controller 2002 may write data to the semiconductor package 2003, or read data from the semiconductor package 2003, and may improve an operation speed of the electronic system 2000.

The DRAM 2004 may include a buffer memory for reducing a speed difference between the semiconductor package 2003, which is a data storage space, and the external host. The DRAM 2004 included in the electronic system 2000 may also operate as a kind of cache memory, and may also provide a space for temporarily storing data in a control operation on the semiconductor package 2003. When the DRAM 2004 is included in the electronic system 2000, the memory controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b, which are apart from each other. Each of the first and second semiconductor packages 2003a and 2003b may include a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 arranged on a lower surface of each of the plurality of semiconductor chips 2200, a connection structure 2400 electrically connecting the plurality of semiconductor chips 2200 to the package substrate 2100, and a molding layer 2500 covering the plurality of semiconductor chips 2200 and the connection structure 2400 on the package substrate 2100.

The package substrate 2100 may include a printed circuit board including a plurality of package upper pads 2130. Each of the plurality of semiconductor chips 2200 may include an I/O pad 2210. The I/O pad 2210 may correspond to the I/O pad 1101 in FIG. 14. Each of the plurality of semiconductor chips 2200 may include at least one of the semiconductor devices 10, 100, 100a, 100b, 100c, 100d, 100e, 200, 300, 300a, 300b, 300c, 300d, 300e, and 400 described with reference to FIGS. 1 through 13.

In some embodiments, the connection structure 2400 may include a bonding wire electrically connecting the I/O pad 2210 to the package upper pad 2130. Accordingly, in the first and second semiconductor packages 2003a and 2003b, the plurality of semiconductor chips 2200 may be electrically connected to each other by using a bonding wire method, and may be electrically connected to the package upper pad 2130 of the package substrate 2100. According to some embodiments, in the first and second semiconductor packages 2003a and 2003b, the plurality of semiconductor chips 2200 may also be electrically connected to each other by a connection structure including through silicon vias TSV, instead of the connection structure 2400 of a bonding wire method.

In some embodiments, the memory controller 2002 and the plurality of semiconductor chips 2200 may also be included in one package. In an embodiment, the memory controller 2002 and the plurality of semiconductor chips 2200 may be mounted on an interposer substrate discretely different from the main substrate 2001, and the memory controller 2002 and the plurality of semiconductor chips 2200 may also be connected to each other by distribution formed on the interposer substrate.

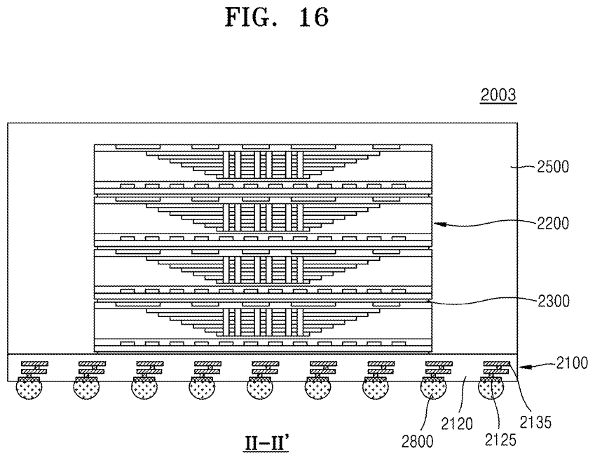

FIG. 16 is a schematic cross-sectional view of a semiconductor package 2003 according to some embodiments. Referring to FIG. 16, in the semiconductor package 2003, the package substrate 2100 may include a printed circuit board. The package substrate 2100 may include a package substrate body unit 2120, the plurality of package upper pads 2130 (refer to FIG. 15) arranged on an upper surface of the package substrate body unit 2120, a plurality of lower pads 2125 arranged on a lower surface of the package substrate body unit 2120 or exposed via the lower surface thereof, and a plurality of internal distribution 2135 electrically connecting the plurality of package upper pads 2130 (refer to FIG. 15) to the plurality of lower pads 2125 in the package substrate body unit 2120. As illustrated in FIG. 15, the plurality of package upper pads 2130 may be electrically connected to a plurality of connection structure 2400. As illustrated in FIG. 16, the plurality of lower pads 2125 may be connected to the plurality of distribution patterns 2005 on the main substrate 2001 of the electronic system 2000 illustrated in FIG. 15 via a plurality of conductive bumps 2800. Each of the plurality of semiconductor chips 2200 may include at least one of the semiconductor devices 10, 100, 100a, 100b, 100c, 100d, 100e, 200, 300, 300a, 300b, 300c, 300d, 300e, and 400 described with reference to FIGS. 1 through 13.

By way of summation and review, Embodiments are directed to a semiconductor device that has excellent electrical characteristics and that can be manufactured in a low-temperature process. Embodiments further provide an electronic system including the semiconductor device. It will be understood by those of skill in the art that various changes in for and details may be made without departing from the spirit and scope of the present invention as set forth in the following claims.

What is claimed is:

1. A semiconductor device comprising:
a plurality of gate electrodes spaced apart from each other in a vertical direction on a substrate;
a plurality of channel structures respectively penetrating the plurality of gate electrodes and extending in the vertical direction, and each including a channel layer having a stacked structure of a first oxide semiconductor channel layer and a second oxide semiconductor channel layer which have different conductivities, and a gate insulating layer disposed between the channel layer and each of the plurality of gate electrodes; and
a plurality of bit lines disposed on the plurality of channel structures and respectively connected to the plurality of channel structures,
wherein the gate insulating layer, the first oxide semiconductor channel layer, and the second oxide semiconductor channel layer are sequentially disposed.

2. The semiconductor device as claimed in claim 1, wherein:
the first oxide semiconductor channel layer has an n-type conductivity and has a first thickness on the gate insulating layer, and
the second oxide semiconductor channel layer has a p-type conductivity and has a second thickness on the gate insulating layer.

3. The semiconductor device as claimed in claim 2, wherein the first thickness is greater than the second thickness.

4. The semiconductor device as claimed in claim 2, wherein the first thickness is equal to the second thickness.

5. The semiconductor device as claimed in claim 1, wherein:
the second oxide semiconductor channel layer has an n-type conductivity and has a first thickness on the gate insulating layer, and
the first oxide semiconductor channel layer has a p-type conductivity and has a second thickness on the gate insulating layer.

6. The semiconductor device as claimed in claim 5, wherein the first thickness is greater than the second thickness.

7. The semiconductor device as claimed in claim 2, wherein the first thickness is equal to the second thickness.

8. The semiconductor device as claimed in claim 1, wherein, a bandgap of one of the first oxide semiconductor channel layer and the second oxide semiconductor channel layer having an n-type conductivity has a greater value than that of a bandgap of the other having a p-type conductivity.

9. A semiconductor device comprising:
a gate stack including a plurality of gate electrodes and a plurality of insulating layers alternately stacked on a substrate;
a plurality of channel structures respectively filling a plurality of channel holes penetrating the gate stack; and
a plurality of bit lines disposed on the plurality of channel structures and respectively connected to the plurality of channel structures,
wherein each of the plurality of channel structures comprises
a gate insulating layer including a blocking dielectric layer, a charge storage layer, and a tunneling dielectric layer conformally and sequentially disposed on a sidewall of each of the plurality of channel holes; and
a channel layer having a stacked structure of a first oxide semiconductor channel layer of an n-type conductivity and a second oxide semiconductor channel layer of a p-type conductivity on the gate insulating layer, wherein a band gap of the first oxide semiconductor channel layer has a greater value than that of a band gap of the second oxide semiconductor channel layer.

10. The semiconductor device as claimed in claim 9, wherein each of the plurality of channel structures further includes:
a buried insulating layer filling a space defined by the channel layer; and
a conductive plug contacting the channel layer and the buried insulating layer and filling an upper side of each of the plurality of channel holes.

11. The semiconductor device as claimed in claim 10, wherein
the first oxide semiconductor channel layer conformally covers the gate insulating layer covering a sidewall of each of the plurality of channel holes and a bottom portion of each of the plurality of channel holes to a first thickness, and
the second oxide semiconductor channel layer conformally covers the first oxide semiconductor channel layer to a second thickness equal to or smaller than the first thickness.

12. The semiconductor device as claimed in claim 10, wherein
the second oxide semiconductor channel layer conformally covers the gate insulating layer covering a sidewall of each of the plurality of channel holes and a bottom portion of each of the plurality of channel holes to a first thickness, and
the first oxide semiconductor channel layer conformally covers the second oxide semiconductor channel layer to a second thickness equal to or greater than the first thickness.

13. The semiconductor device as claimed in claim 9, wherein the channel layer has a pillar shape filling at least a part of a space defined by the gate insulating layer.

14. The semiconductor device as claimed in claim 13, wherein
the first oxide semiconductor channel layer conformally covers the gate insulating layer covering a sidewall of each of the plurality of channel holes and a bottom portion of each of the plurality of channel holes, and
the second oxide semiconductor channel layer fills a space defined by the first oxide semiconductor channel layer.

15. The semiconductor device as claimed in claim 13, wherein
the second oxide semiconductor channel layer conformally covers the gate insulating layer covering a sidewall of each of the plurality of channel holes and a bottom portion of each of the plurality of channel holes, and
the first oxide semiconductor channel layer fills a space defined by the second oxide semiconductor channel layer.

16. The semiconductor device as claimed in claim 9, wherein
the first oxide semiconductor channel layer includes at least one oxide semiconductor material of a quaternary oxide semiconductor material including three different metal atoms or a quinary oxide semiconductor material including four different metal atoms, and
the second oxide semiconductor channel layer includes a binary oxide semiconductor material including one metal element.

17. The semiconductor device as claimed in claim 16, wherein the second oxide semiconductor channel layer includes a binary oxide semiconductor material including one same metal element among metal elements included in an oxide semiconductor material constituting the first oxide semiconductor channel layer.

18. The semiconductor device as claimed in claim 9, wherein
the first oxide semiconductor channel layer includes at least one of indium gallium tin oxide (IGTO), indium gallium zinc oxide (IGZO), or indium gallium zinc tin oxide (IGZTO), and
the second oxide semiconductor channel layer includes at least one of tin oxide (SnO), tellurium oxide (TeO), copper oxide (CuO), bismuth oxide (BiO), or nickel oxide (NiO).

19. An electronic system comprising:
a main substrate;
a semiconductor device on the main substrate; and
a controller electrically connected to the semiconductor device on the main substrate,
wherein the semiconductor device includes:
a plurality of gate electrodes spaced apart from each other in a vertical direction on the main substrate;
a plurality of channel structures respectively penetrating the plurality of gate electrodes and extending in the vertical direction;
a plurality of bit lines disposed on the plurality of channel structures and respectively connected to the plurality of channel structures;
a peripheral circuit electrically connected to the plurality of gate electrodes and the plurality of bit lines; and
an input/output pad electrically connected to the peripheral circuit,
wherein each of the plurality of channel structures comprises a channel layer having a stacked structure of a first oxide semiconductor channel layer and a second oxide semiconductor channel layer having different conductivities, and a gate insulating layer disposed between the channel layer and each of the plurality of gate electrodes, and
the gate insulating layer, the first oxide semiconductor channel layer, and the second oxide semiconductor channel layer are sequentially disposed.

20. The electronic system as claimed in claim 19, wherein
the first oxide semiconductor channel layer has an n-type conductivity and has a first thickness on the gate insulating layer, and
the second oxide semiconductor channel layer has a p-type conductivity and has a second thickness smaller than the first thickness on the gate insulating layer.
